(19) United States
(12) Patent Application Publication
(10) Pub. No.: US 2026/0130203 A1
(43) Pub. Date: May 7, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Chih-Hong HWANG, New Taipei City (TW); Jhon-Jhy LIAW, Zhudong Township, Hsinchu County (TW)

(21) Appl. No.: 18/937,367

(22) Filed: Nov. 5, 2024

(51) Int. Cl. H01L 23/528; H01L 29/06; H01L 29/417; H01L 29/423; H01L 29/66; H01L 29/775; H01L 29/786

(52) U.S. Cl. CPC H10W 20/427; H10D 30/014; H10D 30/43; H10D 30/6729; H10D 30/6735; H10D 30/6757; H10D 62/121; H10D 64/017; H10D 64/254

(57) ABSTRACT

A semiconductor structure is provided. The semiconductor structure includes a lower fin element, an isolation structure surrounding the lower fin element, and a functional circuit and an electrical connection structure. The functional circuit includes a set of nanostructures over the lower fin element, and a gate stack wrapping around the set of nanostructures. The electrical connection structure includes a through via embedded in the isolation structure, and a plurality of gate rails and a plurality of contact rails that are arranged horizontally in an alternating manner on the through via.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A, 2C, 2E, 2F and 2I are layouts (top views) illustrating the formation of a semiconductor structure at various intermediate stages, in accordance with some embodiments of the disclosure.

FIGS. 2A-1, 2A-2 and 2A-3 are cross-sectional views of the semiconductor structure at one of the intermediate stages corresponding to line X-X, line Y1-Y1 and line Y2-Y2 of FIG. 2A, in accordance with some embodiments of the disclosure.

FIGS. 2B-1, 2B-2 and 2B-3 are cross-sectional views of the semiconductor structure at one of the intermediate stages corresponding to line X-X, line Y1-Y1 and line Y2-Y2 of FIG. 2A, in accordance with some embodiments of the disclosure.

FIGS. 2C-1, 2C-2 and 2C-3 are cross-sectional views of the semiconductor structure at one of the intermediate stages corresponding to line X-X, line Y1-Y1 and line Y2-Y2 of FIG. 2C, in accordance with some embodiments of the disclosure.

FIGS. 2D-1, 2D-2 and 2D-3 are cross-sectional views of the semiconductor structure at one of the intermediate stages corresponding to line X-X, line Y1-Y1 and line Y2-Y2 of FIG. 2C, in accordance with some embodiments of the disclosure.

FIGS. 2E-1, 2E-2 and 2E-3 are cross-sectional views of the semiconductor structure at one of the intermediate stages corresponding to line X-X, line Y1-Y1 and line Y2-Y2 of FIG. 2E, in accordance with some embodiments of the disclosure.

FIGS. 2F-1, 2F-2 and 2F-3 are cross-sectional views of the semiconductor structure at one of the intermediate stages corresponding to line X-X, line Y1-Y1 and line Y2-Y2 of FIG. 2F, in accordance with some embodiments of the disclosure.

FIGS. 2G-1, 2G-2 and 2G-3 are cross-sectional views of the semiconductor structure at one of the intermediate stages corresponding to line X-X, line Y1-Y1 and line Y2-Y2 of FIG. 2F, in accordance with some embodiments of the disclosure.

FIGS. 2H-1, 2H-2 and 2H-3 are cross-sectional views of the semiconductor structure at one of the intermediate stages corresponding to line X-X, line Y1-Y1 and line Y2-Y2 of FIG. 2F, in accordance with some embodiments of the disclosure.

FIGS. 2I-1, 2I-2 and 2I-3 are cross-sectional views of the semiconductor structure at one of the intermediate stages corresponding to line X-X, line Y1-Y1 and line Y2-Y2 of FIG. 21, in accordance with some embodiments of the disclosure.

FIGS. 3A and 3B are schematic views illustrating an electrical transmission route including an electrical connection cell region, in accordance with some embodiments of the disclosure.

FIG. 4 is a layout (top view) illustrating a semiconductor structure, in accordance with some embodiments of the disclosure.

FIGS. 4-1 and 4-2 are cross-sectional views of the semiconductor structure corresponding to line Y1-Y1 and line Y2-Y2 of FIG. 4, in accordance with some embodiments of the disclosure.

FIGS. 5A, 5B and 5C are modifications of the semiconductor structure of FIG. 2I-1, in accordance with some embodiments of the disclosure.

FIG. 6 is a layout (top view) illustrating a semiconductor structure, in accordance with some embodiments of the disclosure.

FIG. 7 is a layout (top view) illustrating a semiconductor structure, in accordance with some embodiments of the disclosure.

FIGS. 7-1 and 7-2 are cross-sectional views of the semiconductor structure corresponding to line Y1-Y1 and line Y2-Y2 of FIG. 7, in accordance with some embodiments of the disclosure.

FIG. 8 is a layout (top view) illustrating a semiconductor structure, in accordance with some embodiments of the disclosure.

FIG. 9 is a layout (top view) illustrating a semiconductor structure, in accordance with some embodiments of the disclosure.

FIGS. 9-1, 9-2 and 9-3 are cross-sectional views of the semiconductor structure corresponding to line X-X, line Y1-Y1 and line Y2-Y2 of FIG. 9, in accordance with some embodiments of the disclosure.

FIG. 10 is a layout (top view) illustrating a semiconductor structure, in accordance with some embodiments of the disclosure.

FIG. 11 is a layout (top view) illustrating a semiconductor structure, in accordance with some embodiments of the disclosure.

FIG. 11-1 is a cross-sectional view of the semiconductor structure corresponding to line X-X of FIG. 11, in accordance with some embodiments of the disclosure.

FIG. 12 is a layout (top view) illustrating a semiconductor structure, in accordance with some embodiments of the disclosure.

FIG. 12-1 is a cross-sectional view of the semiconductor structure corresponding to line X-X of FIG. 12, in accordance with some embodiments of the disclosure.

FIG. 13 is a modification of the semiconductor structure FIG. 2I-3, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned using any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure are provided. The aspect of the present disclosure is directed to a semiconductor structure with an electrical connection structure. The electrical connection structure may be configured to transfer an electronic signal and/or to supply power from the frontside to the backside and/or from the backside to the frontside of the device. Therefore, the complexity of the metal routing on the frontside of the substrate may be reduced, which may facilitate the continued scaling of semiconductor devices.

In the embodiments of the present disclosure, the electrical connection structure may include a plurality of gate rails, which are formed together with the gate stacks of the function circuit. The electrical connection structure may further include a plurality of contact rails, which are formed together with the contact plugs of the function circuit. Therefore, the process of manufacturing the electrical connection structure may be easily integrated into the CMOS manufacturing process, and the resistance of the electrical connection structure may be significantly reduced. Therefore, the IR voltage drop of the resulting semiconductor device may be reduced.

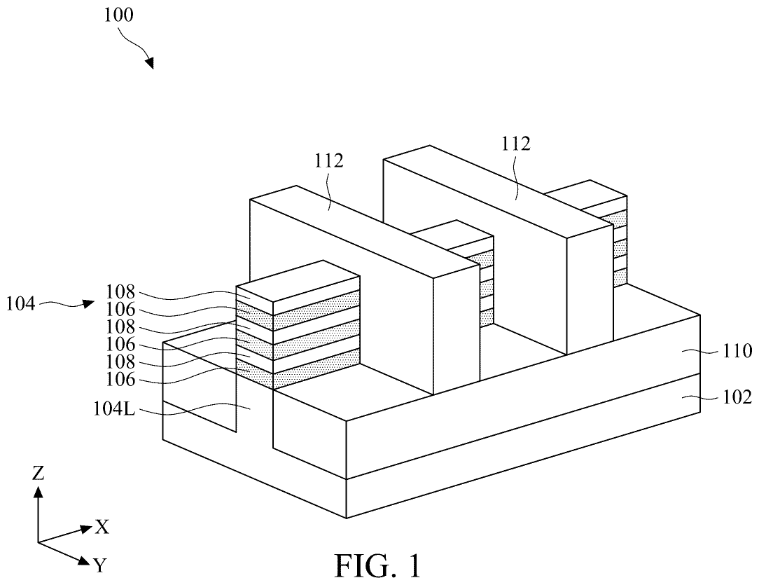

FIG. 1 is a perspective view of a semiconductor structure 100, in accordance with some embodiments of the disclosure. The semiconductor structure 100 includes a substrate 102 and a fin structure 104 over the substrate 102, as shown in FIG. 1, in accordance with some embodiments. The fin structure 104 is the active region of the semiconductor structure 100, in accordance with some embodiments. The fin structure 104 includes a lower fin element 104L formed from the substrate 102, in accordance with some embodiments. The lower fin element 104L is surrounded by an isolation structure 110, in accordance with some embodiments. The fin structure 104 further includes an upper fin element formed from an epitaxial stack including alternating first semiconductor layers 106 and second semiconductor layers 108, in accordance with some embodiments. The second semiconductor layers 108 will form nanostructures (e.g., nanowires or nanosheets) and serve as the channel for the resulting semiconductor devices, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104 extends in the X direction, in accordance with some embodiments. That is, the fin structure 104 has a longitudinal axis parallel to the X direction, in accordance with some embodiments. The X direction may also be referred to as the channel-extending direction. The current of the resulting semiconductor device (i.e., nanostructure transistor) flows in the X direction through the channel. The fin structure 104 is defined as several channel regions and several source/drain regions, where the channel regions and the source/drain regions are alternately arranged, in accordance with some embodiments. It is noted that in the present disclosure, source/drain region(s) or source/drain feature(s) may refer to a source or a drain, individually or collectively dependent upon the context.

Gate structures 112 are formed with longitudinal axes parallel to the Y direction and extending across and/or surrounding the channel regions of the fin structure 104, in accordance with some embodiments. The source/drain regions of the fin structure 104 are exposed from the gate structure 112, in accordance with some embodiments. The Y direction may also be referred to as a gate-routing direction.

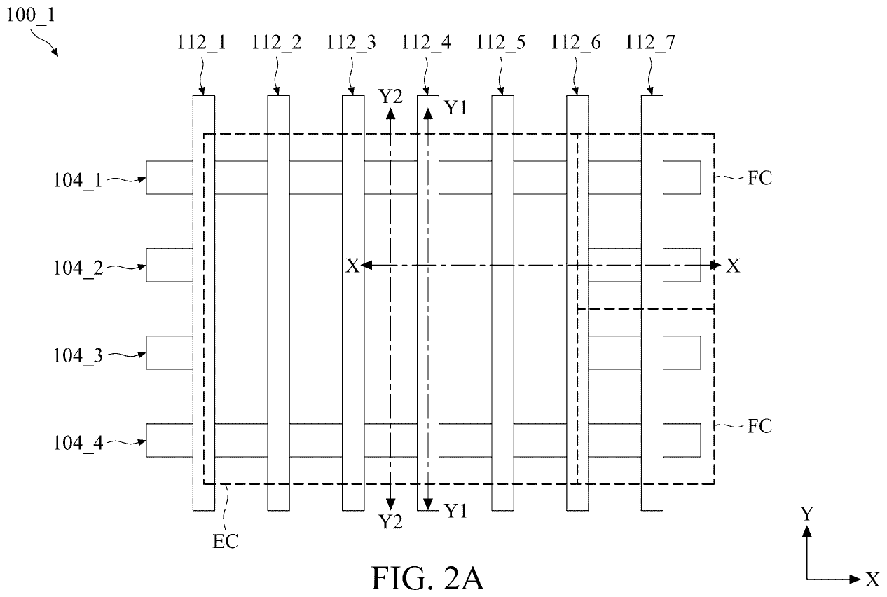

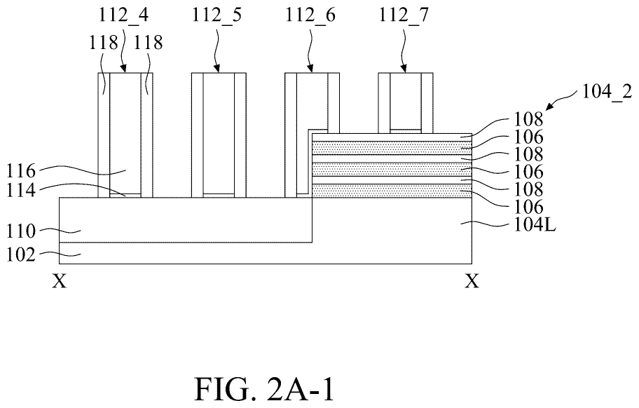

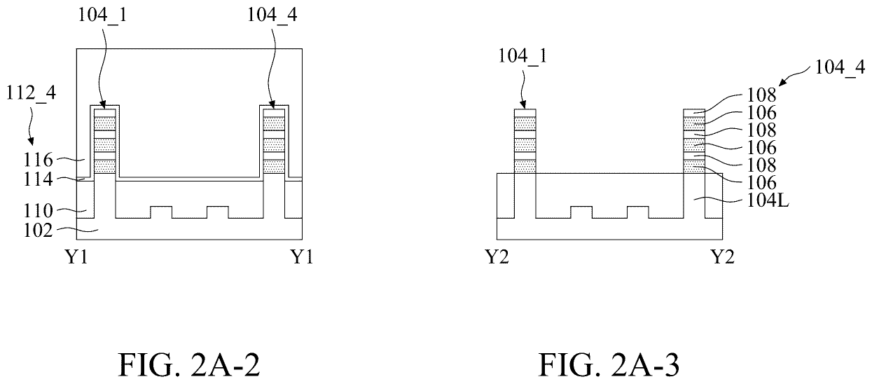

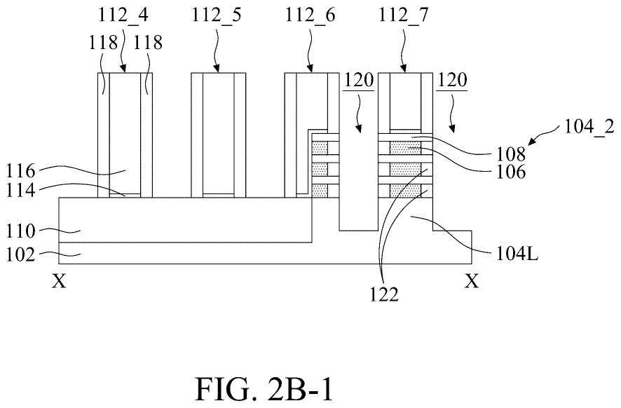

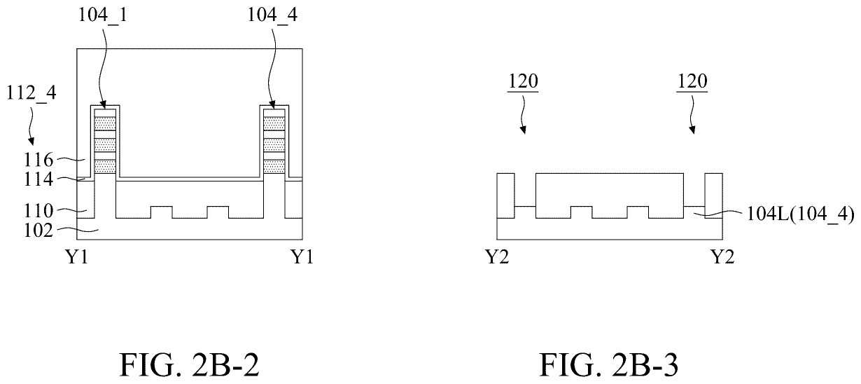

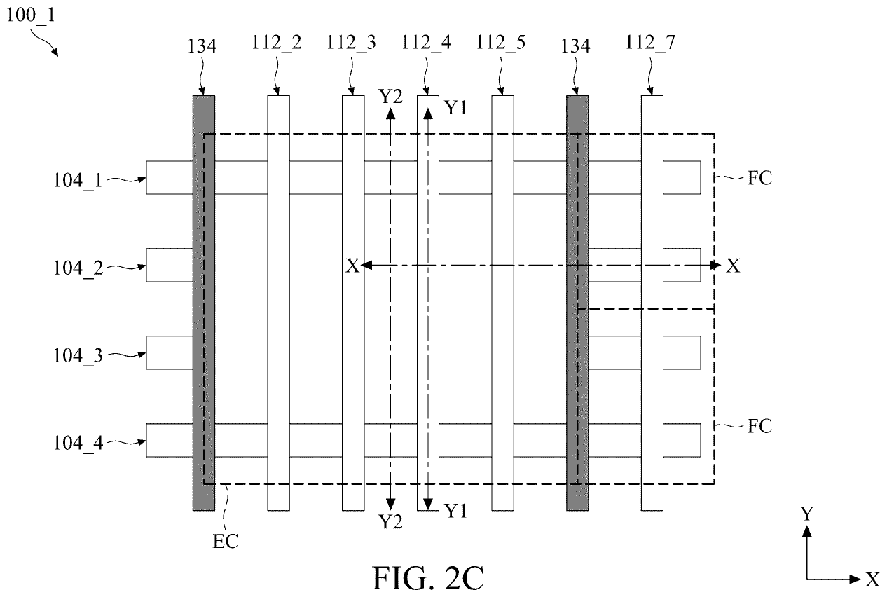

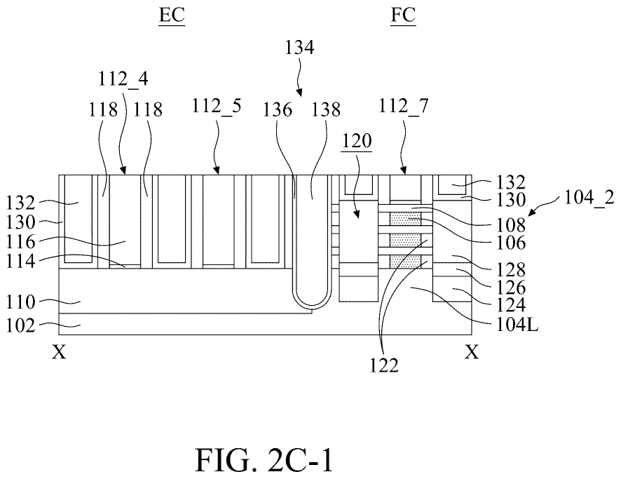

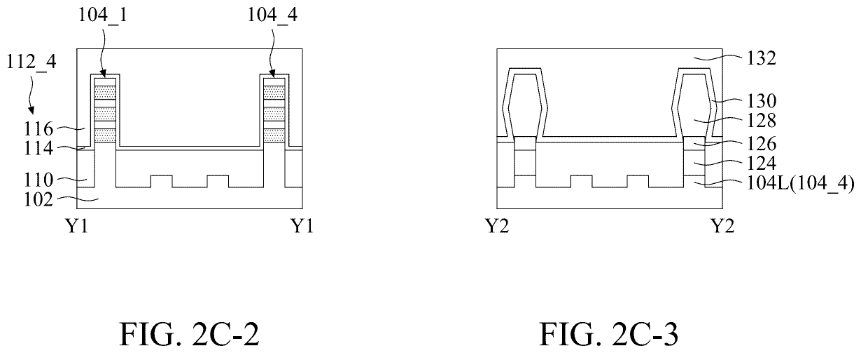

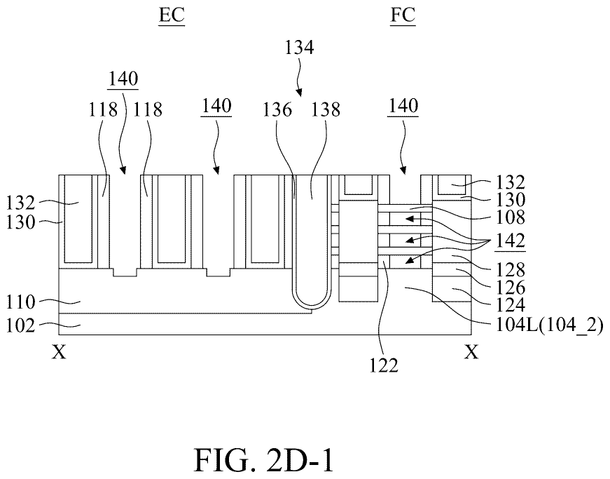

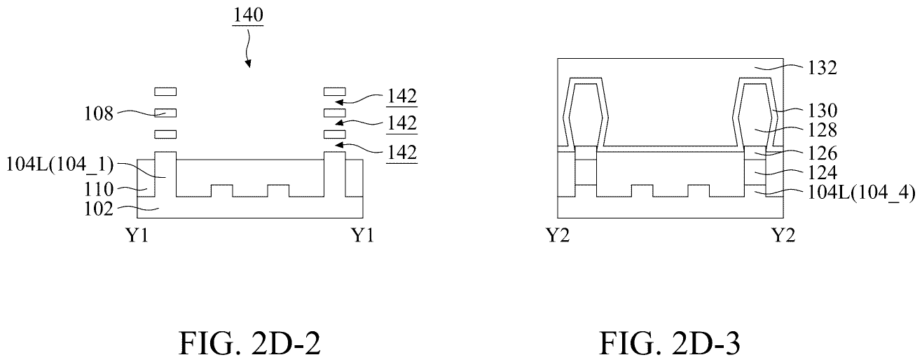

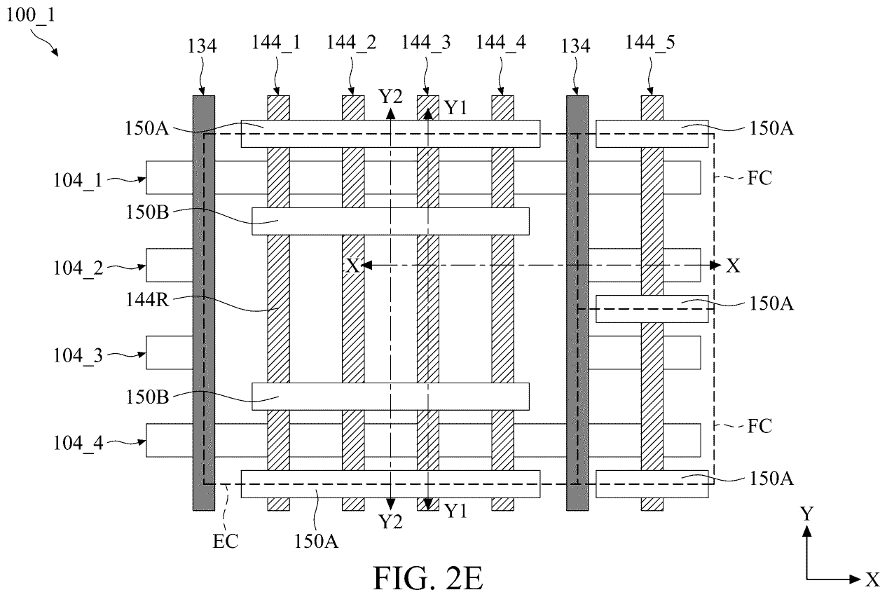

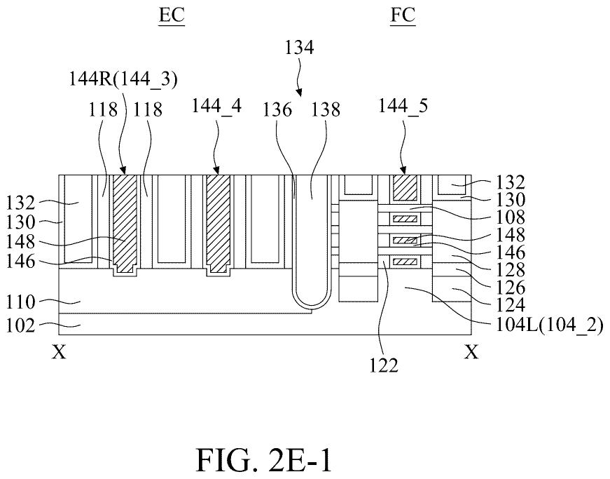

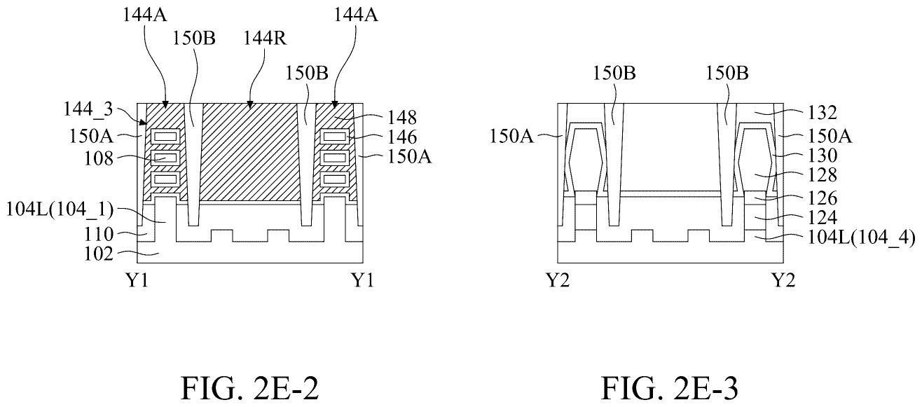

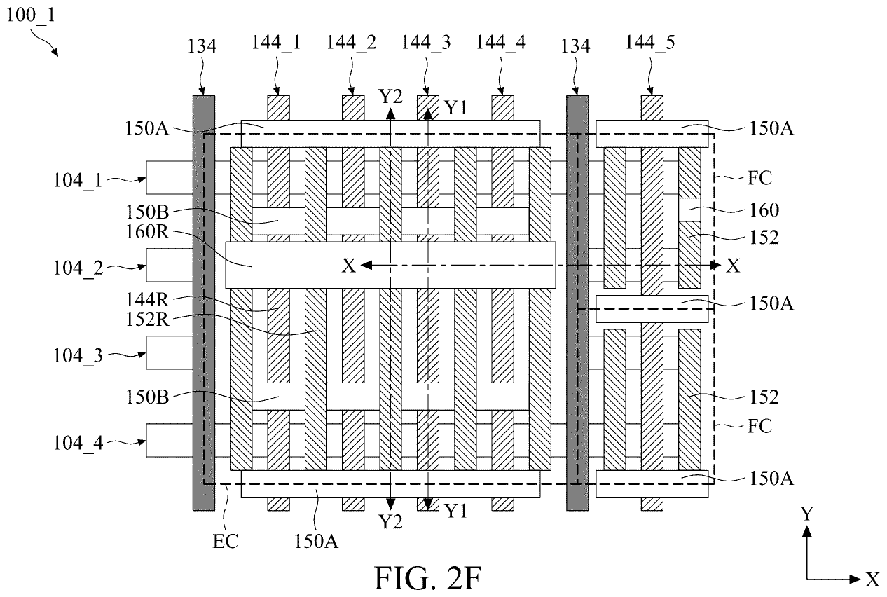

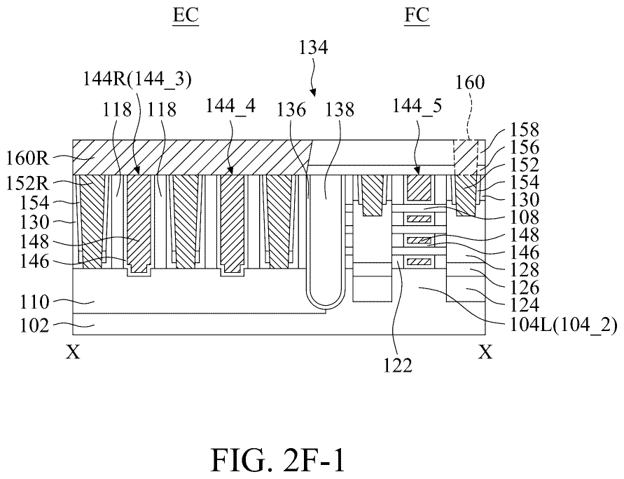

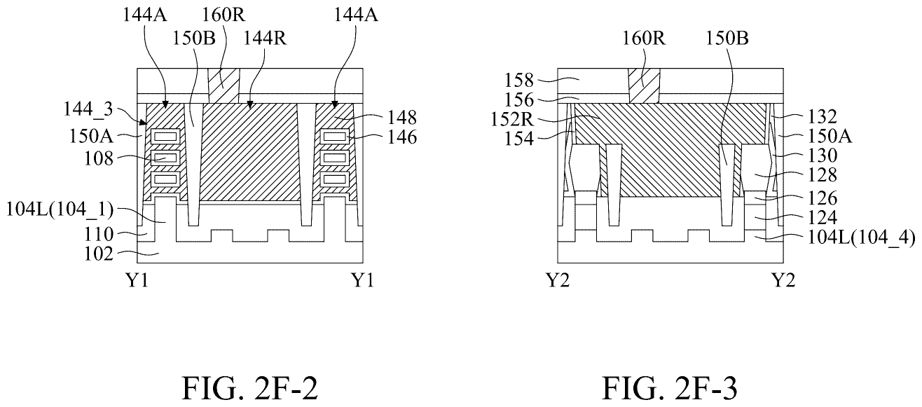

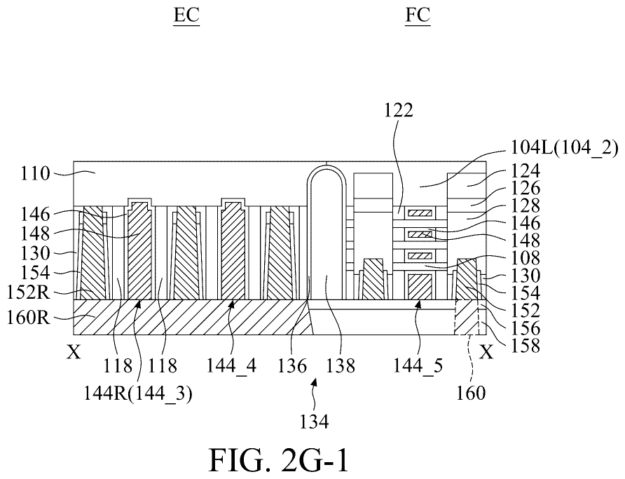

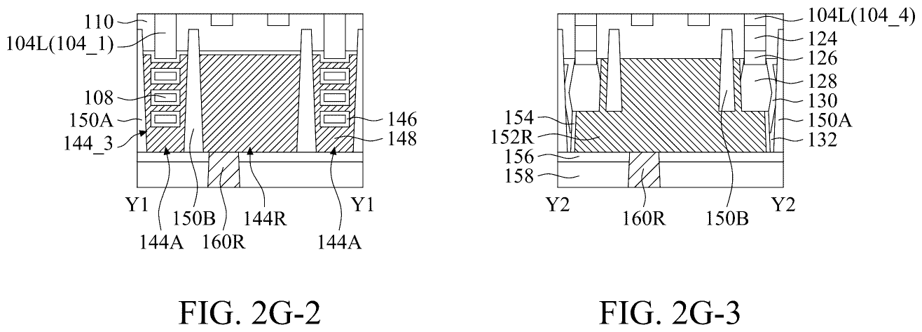

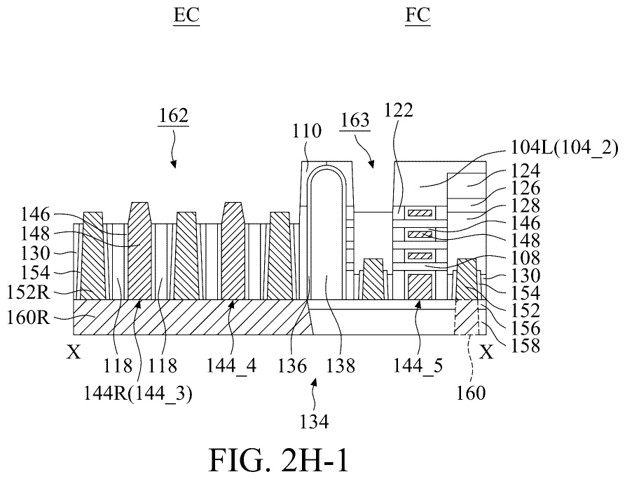

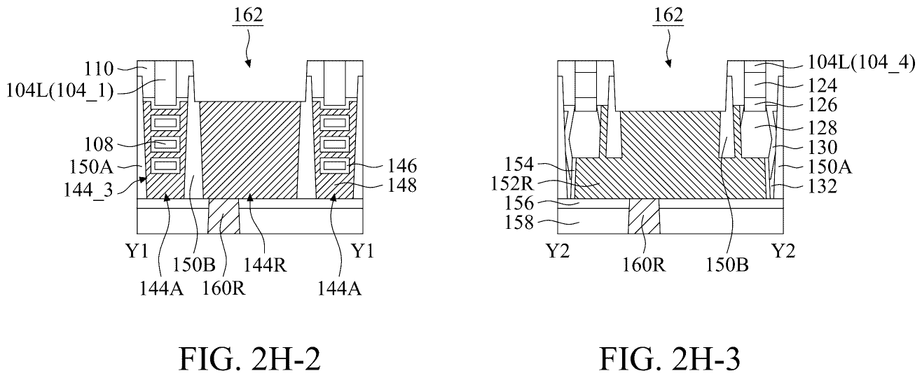

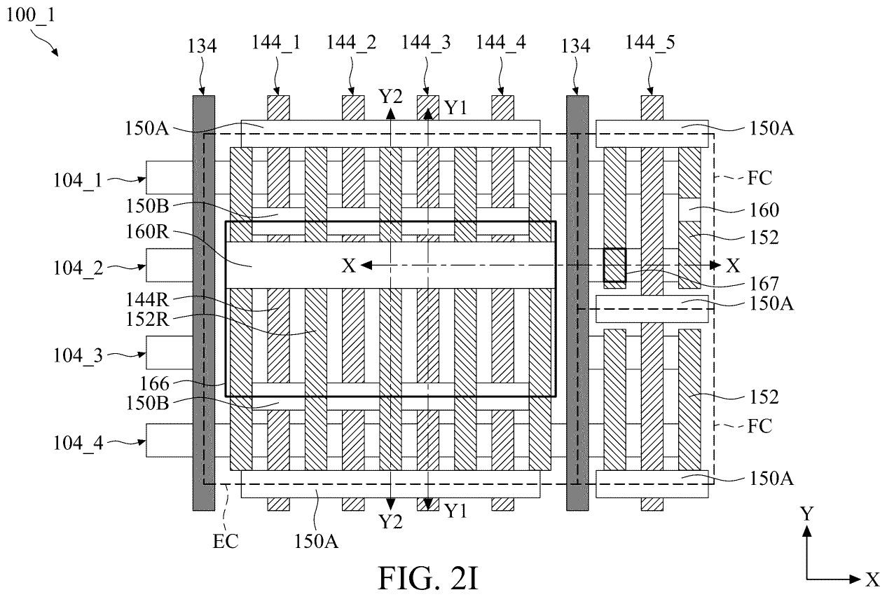

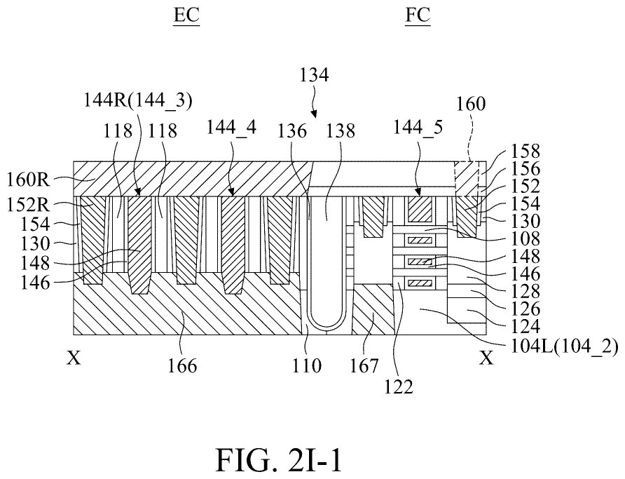

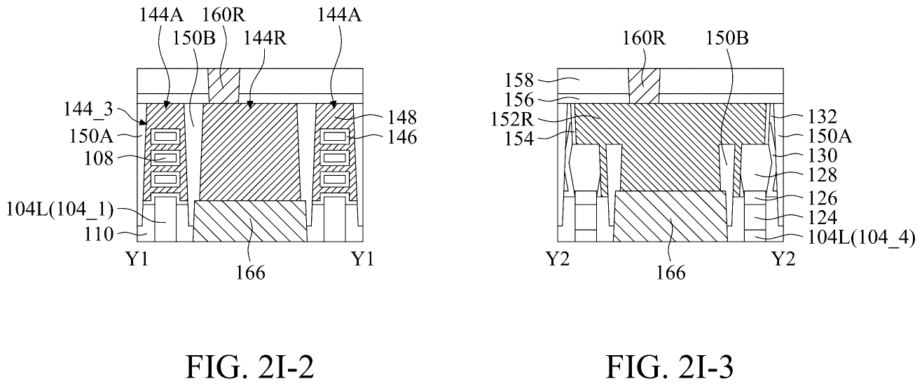

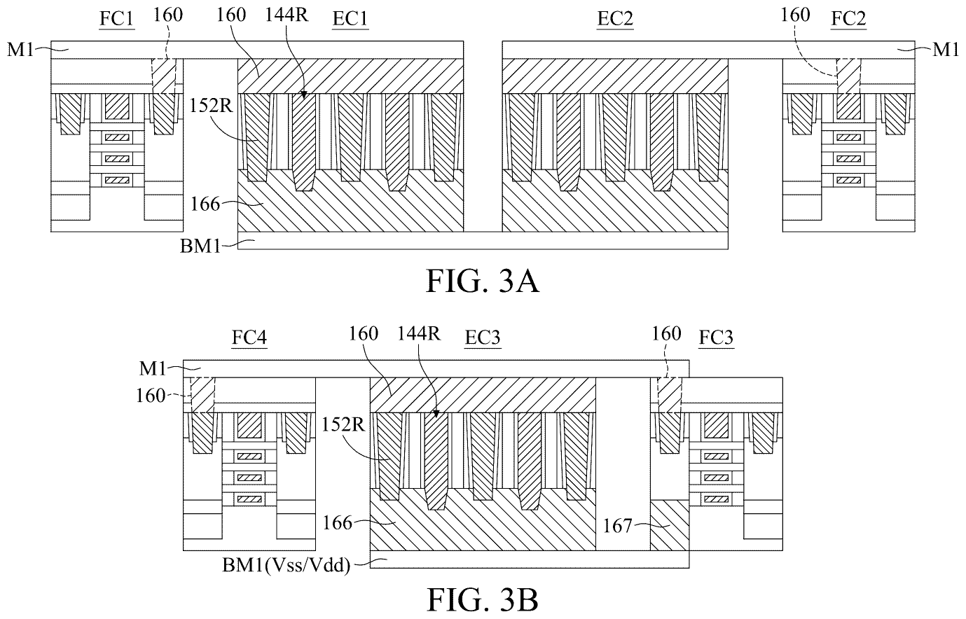

FIGS. 2A through 2I-3 are schematic views illustrating the formation of a semiconductor structure 100_1 at various intermediate stages, in accordance with some embodiments of the disclosure. FIG. 2A is a plan view of a semiconductor structure 100_1 after the formation of active regions 104, an isolation structure 110, dummy gate structures 112 and gate spacer layers 118. FIGS. 2A-1, 2A-2 and 2A-3 are cross-sectional views corresponding to line X-X, line Y1-Y1 and line Y2-Y2 of FIG. 2A.

The semiconductor structure 100_1 includes a substrate 102 and a plurality of active regions 104 (including 104_1 through 104_4) over the substrate 102, as shown in FIGS. 2A to 2A-3, in accordance with some embodiments. The frontside of the semiconductor structure 100_1 (or the substrate 102) faces upward, in accordance with some embodiments.

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

Some areas of the substrate 102 are defined as functional circuit cell regions FC and electrical connection cell regions EC, as shown in FIG. 2A, in accordance with some embodiments. The functional circuit cell regions FC may be memory cell regions (e.g., SRAM cell regions) or logic cell regions (e.g., NOR, AND, OR, Flip-Flop, and/or SCAN cell regions), in accordance with some embodiments. In some embodiments, the functional circuit cell regions FC are standard cell regions. A functional circuit which is formed of a plurality of functional transistors interconnected with each other will be formed in each of the functional circuit cell regions FC, in accordance with some embodiments.

The electrical connection cell region EC is configured to transfer an electronic signal, and/or supply power, in accordance with some embodiments. An electrical connection structure will be formed in the electrical connection cell region EC, and connects between a frontside metal layer and a backside metal layer, in accordance with some embodiments. The electrical connection cell region EC does not have a functional transistor therein. The formation of the functional circuits in the functional circuit cell regions FC and the electrical connection structure in the electrical connection cell region EC will be discussed in detail below.

In some embodiments, the cell height (dimension in the Y direction) of the electrical connection cell region EC is twice the cell height (dimension in the Y direction) of functional circuit cell regions FC. In some other embodiments, the cell height of the electrical connection cell region EC is several times (e.g., 3 to 10 times) the cell height of functional circuit cell regions FC.

The active regions 104_1 to 104_4 extend in the X direction, in accordance with some embodiments. That is, the active regions 104 have longitudinal axes parallel to the X direction, in accordance with some embodiments. In some embodiments, the active regions 104 are fin structures 104 of FIG. 1. The formation of the active regions 104 includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor device (such as nanostructure transistors), in accordance with some embodiments. Although three first semiconductor layers 106 and three second semiconductor layers 108 are shown, the number is not limited to three, and can be two or four, and is less than ten.

The formation of the active regions 104 further includes forming a patterned mask layer (not shown) over the epitaxial stack, and then etching the epitaxial stack and underlying substrate 102 using the patterned mask layer, thereby forming trenches and the active regions 104 protruding from between trenches, in accordance with some embodiments. Portions of the substrate 102 protruding from between the trenches serve as lower fin elements 104L of the active regions 104, in accordance with some embodiments. The remainder of the epitaxial stack (including the first semiconductor layers 106 and the second semiconductor layers 108) serves as upper fin elements of the active regions 104, in accordance with some embodiments.

A second active region patterning process may be performed to cut the active regions 104_2 and 104_3 into several segments within the functional circuit cell regions FC, as show in FIGS. 2A and 2A-1. The second active region patterning process may include photolithography and etching processes. In the second patterning process, the upper fin elements of the active regions 104_2 and 104_3 within the electrical connection cell region EC are removed as shown in FIGS. 2A to 2A-3, in accordance with some embodiments. In some embodiments, the lower fin elements 104L of the active regions 104_2 and 104_3 may also be recessed, or alternatively entirely removed.

The active regions 104_1 and 104_4 are continuous oxide definition (CNOD) features, which are elongated semiconductor strips and extend continuously across the functional circuit cell regions FC and the electrical connection cell region EC, in accordance with some embodiments. The active regions 104_2 and 104_3 may be also referred to as cut OD (COD) features, and located within the functional circuit cell regions FC, in accordance with some embodiments.

An isolation structure 110 is formed to surround the lower fin elements 104L of the active regions 104, in accordance with some embodiments. The isolation structure 110 is configured to electrically isolate the active regions 104 from each other and is also referred to as shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104, in accordance with some embodiments. The planarization may be chemical mechanical polishing (CMP), an etching back process, or a combination thereof. The insulating material is then recessed by an etching process (such as dry plasma etching and/or wet chemical etching) until the upper fin elements of the active regions 104 are exposed, in accordance with some embodiments.

Dummy gate structures 112 (including 112_1 to 112_7) are formed over and/or across the active regions 104 and the isolation structure 110, as shown in FIGS. 2A, 2A-1 and 2A-2, in accordance with some embodiments. The dummy gate structures 112 are configured as sacrificial structures and will be replaced with final gate stacks and insulating strips, in accordance with some embodiments. In some embodiments, the dummy gate structures 112 extend in the Y direction. That is, the dummy gate structures 112 have longitudinal axes parallel to the Y direction, in accordance with some embodiments.

The dummy gate structures 112_2 to 112_5 extend through the electrical connection cell region EC; the dummy gate structure 112_7 extends through the functional circuit cell regions FC; and the dummy gate structures 112_1 and 112_6 extend along and overlap the Y-direction extending boundary (or edge) of the electrical connection cell region EC, in accordance with some embodiments.

Although four dummy gate structures 112 are illustrated as extending through the electrical connection cell region EC, the number of the dummy gate structures 112 may be 1-10, which may depend on the balance of the substrate area usage and the resistance of the resulting electrical connection structure. In addition, although one dummy gate structure extends through the functional circuit cell regions FC, the number of the dummy gate structures 112 may be 2-10, which may depend on the design demand of the resulting integrated circuit.

The dummy gate structures 112 surround the channel regions of the active regions 104, in accordance with some embodiments. Each of the dummy gate structures 112 includes a dummy gate dielectric layer 114 and a dummy gate electrode layer 116 over the dummy gate dielectric layer 114, in accordance with some embodiments. In some embodiments, the dummy gate dielectric layer 114 is conformally formed along the upper fin elements of the active regions 104 and the top surface of the isolation structure 110. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof.

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof. In some embodiments, the formation of the dummy gate structures 112 includes depositing a dielectric material for the dummy gate dielectric layer 114 over the semiconductor structure 100_1, depositing a material for the dummy gate electrode layer 116 over the dielectric material, planarizing the material for the dummy gate electrode layer 116, and patterning the material for the dummy gate electrode layer 116 and the dielectric material into the dummy gate structures 112 using photolithography and etching processes.

Gate spacer layers 118 are formed along opposite sidewalls of the dummy gate structures 112, as shown in FIG. 2A-1, in accordance with some embodiments. The gate spacer layers 118 extend in the Y direction and across the active regions 104 and the isolation structure 110, in accordance with some embodiments. The gate spacer layers 118 are used to offset the subsequently formed source/drain features and separate the source/drain features from the gate structure, in accordance with some embodiments. In some embodiments, the gate spacer layer 118 is made of dielectric material such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the formation of the gate spacer layers 118 includes globally and conformally depositing the dielectric material, followed by an anisotropic etching process. In some embodiments, the etching process is performed without an additional photolithography process.

FIGS. 2B-1, 2B-2 and 2B-3 are cross-sectional views of a semiconductor structure 100_1 after the formation of source/drain recesses 120 and inner spacer layers 122 corresponding to line X-X, line Y1-Y1 and line Y2-Y2 of FIG. 2A.

An etching process is performed to recess the source/drain regions of the active regions 104, thereby forming source/drain recesses 120, as shown in FIGS. 2B-1 and 2B-3, in accordance with some embodiments. The etching process may be an anisotropic etching process such as dry plasma etching, an isotropic etching process such as dry chemical etching, remote plasma etching or wet chemical etching, and/or a combination thereof. The gate spacer layers 118 and the dummy gate structure 112 may serve as etch masks such that the source/drain recesses 120 are formed self-aligned on opposite sides of the dummy gate structures 112, in accordance with some embodiments. The bottoms of the source/drain recesses 120 extend into the lower fin elements 104L, in accordance with some embodiments.

An etching process laterally recesses, from the source/drain recesses 120, the first semiconductor layers 106, thereby forming notches, and inner spacer layers 122 are formed in the notches, as shown in FIG. 2B-1, in accordance with some embodiments. The inner spacer layers 122 are formed to abut the recessed side surfaces of the first semiconductor layers 106, in accordance with some embodiments. In some embodiments, the inner spacer layers 122 are located directly below the gate spacer layers 118.

In some embodiments, the inner spacer layers 122 are made of dielectric material, such as silicon oxide (SiO₂), silicon nitride (SiN), silicon carbide (SIC), silicon oxynitride (SiON), silicon carbon nitride (SiCN), silicon oxycarbonitride (SiOCN), and/or oxygen-doped silicon carbonitride (Si(O)CN). The inner spacer layers may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 122 are formed by depositing a dielectric material over the semiconductor structure 100_1 to overfill the notches, and then etching back the dielectric material to remove the dielectric material outside the notches 150. Portions of the dielectric material left in the notches serve as inner spacer layers 122, in accordance with some embodiments.

FIG. 2C is a plan view of a semiconductor structure 100_1 after the formation of semiconductor isolation features 124, dielectric isolation features 126, source/drain features 128. A contact etching stop layer 130, a first interlayer dielectric layer 132 and insulating strip 134. FIGS. 2C-1, 2C-2 and 2C-3 are cross-sectional views corresponding to line X-X, line Y1-Y1 and line Y2-Y2 of FIG. 2C.

Semiconductor isolation features 124 are formed in the source/drain recesses 120 on the lower fin elements 104L, as shown in FIGS. 2C-1 and 2C-3, in accordance with some embodiments. In some embodiments, the semiconductor isolation features 124 are made of an epitaxial semiconductor material such as non-doped silicon, formed by MBE, MOCVD, or VPE, another suitable technique, or a combination thereof.

Dielectric isolation features 126 are formed over the semiconductor isolation features 124 in the source/drain recesses 120, as shown in FIGS. 2C-1 and 2C-3, in accordance with some embodiments. The dielectric isolation features 126 is configured to reduce the parasitic capacitance of the resulting semiconductor device. In some embodiments, the dielectric isolation features 126 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN), or high-k dielectric material (e.g., with dielectric constant greater than about 7.9) such as LaO, AlO, AlON, ZrO, HfO, ZnO, ZrN, ZrAlO, TiO, TaO, YO, TaCN, or a combination thereof. In some embodiments, the dielectric isolation features 126 are deposited using a technique such as ALD, CVD (such as HDP-CVD, LPCVD or PECVD), another suitable technique, or a combination thereof, followed by an etching-back process.

Source/drain features 128 are grown from the exposed side surfaces of the second semiconductor layers 108 to fill the source/drain recesses 120 using an epitaxial growth process, as shown in FIGS. 2C-1 and 2C-3, in accordance with some embodiments. The epitaxial growth process may be MBE, MOCVD, or VPE, or another suitable technique. In some embodiments, the source/drain features 128 are formed on the dielectric isolation features 126. In some embodiments where the semiconductor isolation features 124 and the dielectric isolation features 126 are omitted, the source/drain features 128 are formed on the lower fin elements 104L.

In some embodiments, the source/drain features 128 are made of any suitable semiconductor material for n-type semiconductor devices (e.g., n-channel nanostructure transistors) or p-type semiconductor devices (e.g., p-channel nanostructure transistors). In some embodiments, the source/drain features 128 are doped. The concentration of the dopant in the source/drain features 128 in a range from about 1×10¹⁹ cm⁻³ to about 6×10²¹ cm⁻³.

In some embodiments where the resulting transistors are n-channel transistors, the source/drain features 128 are doped with the n-type dopant during the epitaxial growth process. For example, the n-type dopant may be phosphorous (P) or arsenic (As). The n-type source/drain features 128 are made of semiconductor material such as SiP, SiAs, SiCP, SiC, Si, GaAs, another suitable semiconductor material, or a combination thereof. For example, the n-type source/drain features 128 may be the epitaxially grown Si doped with phosphorous to form silicon:phosphor (Si:P) source/drain features and/or arsenic to form silicon:arsenic (Si:As) source/drain feature.

In some embodiments where the resulting transistors are p-channel transistors, the source/drain features 128 are doped with the p-type dopant during the epitaxial growth process. For example, the p-type dopant may be boron (B) or BF₂. The p-type source/drain features 128 are made of semiconductor material such as SiGe, Si, GaAs, another suitable semiconductor material, or a combination thereof. In some embodiments, the p-type source/drain features 128 may be the epitaxially grown SiGe doped with boron (B) to form silicon germanium:boron (SiGe:B) source/drain feature.

A contact etching stop layer 130 is formed over the semiconductor structure 100_1 and covers the source/drain features 128, as shown in FIGS. 2C-1 and 2C-3, in accordance with some embodiments. In some embodiments, the contact etching stop layer 130 is made of dielectric material, such as silicon nitride (SiN), silicon oxide (SiO₂), silicon oxynitride (SiON), silicon carbide (SiC), oxygen-doped silicon carbide (SiC:O), oxygen-doped silicon carbonitride (Si(O)CN), or a combination thereof. In some embodiments, a dielectric material for the contact etching stop layer 130 is deposited over the semiconductor structure 100_1 using CVD (such as LPCVD, PECVD, HDP-CVD, or HARP), ALD, another suitable method, or a combination thereof.

A first interlayer dielectric layer 132 is formed over the contact etching stop layer 130, as shown in FIGS. 2C-1 and 2C-3, in accordance with some embodiments. The first interlayer dielectric layer 132 overfills the space between dummy gate structures 112, in accordance with some embodiments. In some embodiments, the first interlayer dielectric layer 132 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the dielectric material for the first interlayer dielectric layer 132 is deposited using CVD (such as HDP-CVD, PECVD, HARP or FCVD), another suitable technique, or a combination thereof. The dielectric materials of the contact etching stop layer 130 and the first interlayer dielectric layer 132 are removed from the top surface of the dummy gate electrode layer 116, for example using CMP, in accordance with some embodiments.

The dummy gate structures 112_1 and 112_6 are replaced with insulating strips 134, as shown in FIGS. 2C and 2C-1, in accordance with some embodiments. In some embodiments, the insulating strips 134 are formed through the dummy gate structures 112_1 and 112_6 and the underlying active regions 104. In some embodiments, the bottoms of the insulating strips 134 are located at a higher position than the bottom surface of the isolation structure 110. In some other embodiments, the bottom of each of the insulating strips 134 may be located at a lower position than the bottom surface of the isolation structure 110.

In some embodiments, each of the active regions 104 is cut through by the insulating strips 134 into several segments. In some embodiments, the insulating strips 134 extend in the Y direction. That is, the insulating strips 134 have longitudinal axes parallel to the Y direction, in accordance with some embodiments. The insulating strips 134 may be also referred to as cut poly gate on oxide definition edge (CPODE) patterns. In some embodiments, the insulating strips 134 are configured to prevent leakage between the neighboring cell regions.

The formation of the insulating strips 134 includes patterning the dummy gate structures 112_1 and 112_6 and the active regions 104 using photolithography and etching processes to form cutting trenches (where the insulating strips 134 are to be formed), depositing a liner 136 and a bulk layer 138 to overfill the cutting trenches, in accordance with some embodiments. The etching process may be an anisotropic etching process such as dry plasma etching, an isotropic etching process such as dry chemical etching, remote plasma etching or wet chemical etching, or a combination thereof. In some embodiments, the deposition process is ALD, CVD (such as LPCVD, PECVD, HDP-CVD, or HARP), another suitable technique, or a combination thereof.

The liner 136 and the bulk layer 138 are dielectric material such as silicon oxide (SiO₂), silicon oxynitride (SiON), silicon nitride (SiN), silicon carbon nitride (SiCN), silicon oxycarbonitride (SiOCN), oxygen-doped silicon carbonitride (Si(O)CN), or a combination thereof. In some embodiments, the insulating strips 134 include dielectric material with k-value greater than 7.9, such as LaO, AlO, AlON, ZrO, HfO, ZnO, ZrN, ZrAlO, TiO, TaO, YO, TaCN, or a combination thereof. In an embodiment, the liner 136 is a silicon oxide layer, and the bulk layer 138 is a silicon nitride layer. A planarization process is then performed on the liner 136 and a bulk layer 138 until the dummy gate structures 112 and the first interlayer dielectric layer 132 are exposed, in accordance with some embodiments. The planarization may be CMP, etching back process, or a combination thereof.

FIGS. 2D-1, 2D-2 and 2D-3 are cross-sectional views of a semiconductor structure 100_1 after the formation of gate trenches 140 and gaps 142 corresponding to line X-X, line Y1-Y1 and line Y2-Y2 of FIG. 2C.

The dummy gate structures 112_2, 112_3, 112_4, 112_5 and 112_7 are removed using one or more etching processes (e.g., an anisotropic etching process such as dry plasma etching, an isotropic etching process such as dry chemical etching, remote plasma etching or wet chemical etching, and/or a combination thereof) to form gate trenches 140 between the gate spacer layers 118, as shown in FIGS. 2D-1 and 2D-2, in accordance with some embodiments. In some embodiments, the gate trenches 140 expose the channel regions of the active regions 104. In some embodiments, the gate trenches 140 also expose the sidewalls of the gate spacer layers 118 facing the channel regions and the top surface of the isolation structure 110.

Afterward, an etching process is performed to remove the first semiconductor layers 106 of the active regions 104 to form gaps 142, as shown in FIGS. 2D-1 and 2D-2, in accordance with some embodiments. The etching process may be an anisotropic etching process such as dry plasma etching, an isotropic etching process such as dry chemical etching, remote plasma etching or wet chemical etching, and/or a combination thereof. The inner spacer layers 122 may be used as an etching stop layer in the etching process, which may protect the source/drain features 128 from being damaged. In some embodiments, the gaps 142 also expose the sidewalls of the inner spacer layers 122 facing the channel regions.

After the one or more etching processes, the four main surfaces of the second semiconductor layers 108 are exposed, in accordance with some embodiments. The exposed second semiconductor layers 108 form several sets of nanostructures 108, in accordance with some embodiments. Each set includes three nanostructures 108 vertically stacked and spaced apart from one other, in accordance with some embodiments. As the term is used herein, “nanostructures” refers to the semiconductor layers with cylindrical shape, bar shaped and/or sheet shape. The nanostructures 108 function as channels of the resulting semiconductor devices (e.g., nanostructure transistors such as GAA transistors), in accordance with some embodiments.

FIG. 2E is a plan view of a semiconductor structure 100_1 after the formation of final gate stacks 144 and gate-cut features 150A and 150B. FIGS. 2E-1, 2E-2 and 2E-3 are cross-sectional views corresponding to line X-X, line Y1-Y1 and line Y2-Y2 of FIG. 2E.

Final gate stacks 144 (including 144_1 to 144_5) are formed in the gate trenches and gaps, thereby wrapping around the nanostructures 108, as shown in FIGS. 2E, 2E-1 and 2E-2, in accordance with some embodiments. In some embodiments, the final gate stacks 144 extend in the Y direction across the active regions 104 and the isolation structure 110. That is, the final gate stacks 144 have longitudinal axes parallel to the Y direction, in accordance with some embodiments. In some embodiments, each of the final gate stacks 144 includes a gate dielectric layer 146 and a metal gate electrode layer 148, in accordance with some embodiments.

The gate dielectric layer 146 may include an interfacial layer and a high-k dielectric layer, in accordance with some embodiments. For example, an oxidation process is performed such that semiconductor material from the nanostructures 108 and the lower fin elements 104L is oxidized to form the interfacial layer. In some embodiments, the interfacial layer is made of a chemically formed silicon oxide or nitrogen-doped silicon oxide.

The high-k dielectric layer is formed conformally along the interfacial layer to wrap around the nanostructures 108, in accordance with some embodiments. The high-k dielectric layer is also conformally formed along the sidewalls of the gate spacer layers 118 facing the channel region, the sidewalls of the inner spacer layers 122 and the top surface of the isolation structure 110, in accordance with some embodiments. In some embodiments, the high-k dielectric layer is dielectric material with high dielectric constant (k value), for example, greater than 7.9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), a combination thereof, or another suitable material. The high-k dielectric layer may be deposited using ALD, PVD, CVD, and/or another suitable technique.

The metal gate electrode layer 148 is formed over the gate dielectric layer 146 and overfills the remainder of the gate trenches 140 and the gaps 142, in accordance with some embodiments. The metal gate electrode layer 148 may be a multi-layer structure with various combinations of a diffusion barrier layer, work function layers with a selected work function to enhance the device performance (e.g., threshold voltage) for n-channel FETs and p-channel FETs, and a metal fill layer to reduce the total resistance of gate stacks, and/or another suitable layer. The metal gate electrode layer 148 may be formed using ALD, PVD, CVD, e-beam evaporation, or another suitable technique. In some embodiments, the metal gate electrode layer 148 may be formed separately for n-channel FETs and p-channel FETs, which may use different work function materials.

A planarization process such as CMP is then performed on the semiconductor structure 100_1 to remove the gate dielectric layer 146 and the metal gate electrode layer 148 from the top surface of the first interlayer dielectric layer 132, in accordance with some embodiments.

The final gate stack 144_5, located in the functional circuit cell regions FC, serves as a functional gate which engages the channel regions so that current can flow between the source/drain regions while in operation, in accordance with some embodiments. The final gate stacks 144 surrounding the nanostructures 108 combines with the neighboring source/drain features 128 to form nanostructure transistors, e.g., n-channel nanostructure transistors and p-channel nanostructure transistors. In some embodiments, the functional circuit in each of the functional circuit cell regions FC includes a plurality of nanostructure transistors (e.g., located at the intersections of the final gate stack 144_5 and the active regions 104_1 to 104_4).

The final gate stacks 144_1 to 144_4, located in the electrical connection cell region EC, serve as a portion of the electrical connection cell structure, in accordance with some embodiments. This will be discussed in detail later. In some embodiments, the nanostructure transistors (e.g., located at the intersections of the final gate stacks 144_1 to 144_4 and the active regions 104_1 and 104_4) in the electrical connection cell region EC are dummy transistors which do not electrically connect to a subsequently formed interconnect structure.

Gate-cut features 150A and 150B are formed in and/or through the final gate stacks 144, the gate spacer layers 118, the contact etching stop layer 130, the first interlayer dielectric layer 132 and the isolation structure 110, as shown in FIGS. 2E, 2E-2 and 2E-3, in accordance with some embodiments. In some embodiments, the gate-cut features 150A and 150B extend in the X direction. That is, the gate-cut features 150A and 150B have longitudinal axes parallel to the X direction, in accordance with some embodiments. The gate-cut features 150A and 150B may be also referred to as a cut metal gate (CMG) pattern.

The gate-cut features 150A extend along and overlaps the X-direction extending boundaries (edge) of the functional circuit cell regions FC and the X-direction extending boundaries (edge) of the electrical connection cell region EC, in accordance with some embodiments. In some embodiments, the gate-cut features 150A are configured to prevent leakage between the neighboring cell regions.

The gate-cut features 150B are located within the electrical connection cell region EC, and located between the active region 104_1 and the portion the active region 104_2, previously removed in the second active region patterning process, and between the active region 104_4 and the portion the active region 104_3, previously removed in the second active region patterning process, in accordance with some embodiments.

The gate-cut features 150A and 150B cut through the final gate stacks 144_1 to 144_4 into several segments electrically isolated from each other, in accordance with some embodiments. The segments of the final gate stacks 144_1 to 144_4 sandwiched between the gate-cut features 150B are referred to gate rails 144R, in accordance with some embodiments. The segments 144A of the final gate stacks 144_1 to 144_4 sandwiched between the gate-cut features 150A and gate-cut features 150B are dummy features, and electrically isolated from the gate rails 144R and the subsequently formed interconnect structure, in accordance with some embodiments.

The gate-cut features 150A and 150B are made of a dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the gate-cut features 150A and 150B include dielectric material with dielectric constant value greater than 7.9, such as LaO, AlO, AlON, ZrO, HfO, ZnO, ZrN, ZrAlO, TiO, TaO, YO, TaCN, or a combination thereof. In some embodiments, the deposition process is ALD, CVD (such as LPCVD, PECVD, HDP-CVD, or HARP), another suitable technique, or a combination thereof.

The formation of the gate-cut features 150A and 150B includes patterning the final gate stacks 144, the gate spacer layers 118, the contact etching stop layer 130, the first interlayer dielectric layer 132 and the isolation structure 110 to form gate-cut trenches (where the gate-cut features 150A and 150B are to be formed) using photolithography and etching processes, in accordance with some embodiments. The etching process may be an anisotropic etching process such as dry plasma etching, an isotropic etching process such as dry chemical etching, remote plasma etching or wet chemical etching, or a combination thereof.

The formation of the gate-cut features 150A and 150B further includes depositing a dielectric material for the gate-cut features 150A and 150B to overfill the gate-cut trenches, in accordance with some embodiments. Afterward, a planarization process is then performed on the dielectric material for the gate-cut features 150A and 150B until the final gate stacks 144, the insulating strips 134 and the first interlayer dielectric layer 132 are exposed, in accordance with some embodiments. The planarization may be CMP, etching back process, or a combination thereof.

FIG. 2F is a plan view of a semiconductor structure 100_1 after the formation of contact plugs 152 and contact rails 152R, an etching stop layer 156, a second interlayer dielectric layer 158, and vias 160 and via rails 160R. FIGS. 2F-1, 2F-2 and 2F-3 are cross-sectional views corresponding to line X-X, line Y1-Y1 and line Y2-Y2 of FIG. 2F.

Contact plugs 152 and contact rails 152R are formed through the first interlayer dielectric layer 132 and the contact etching stop layer 130, as shown in FIGS. 2F, 2F-1 and 2F-3, in accordance with some embodiments. The contact plugs 152 are formed in the functional circuit cell regions FC and used as source or drain terminals of transistors; and the contact rails 152R are formed in the electrical connection cell region EC and used as a portion of the electrical connection structure, in accordance with some embodiments.

In some embodiments, the contact plugs 152 and contact rails 152R extend in the Y direction. That is, the contact plugs 152 and 152R have longitudinal axes parallel to the Y direction, in accordance with some embodiments. The contact plugs 152 and contact rails 152R, overlapping the active regions 104, land on and are electrically connected to the source/drain features 128, in accordance with some embodiments.

The portion of the contact rails 152R between the active regions 104_1 and 104_4 extends to the isolation structure 110, as shown in FIG. 2F-3, in accordance with some embodiments. In some embodiments, the contact rails 152R serve as a portion of the electrical connection cell structure, in accordance with some embodiments. In some embodiments, the contact rails 152R are arranged in an alternating manner in the X direction with the gate rails 144R. In some embodiments, the bottom surfaces of the gate rails 144R are located at a lower position than the bottom surface of the contact rails 152R. In some embodiments, the contact rails 152R are longer than the gate rails 144R in the Y direction.

In some embodiments, the formation of the contact plugs 152 and the contact rails 152R includes patterning the semiconductor structure 100_1 to form contact trenches (where the contact plugs 152 and contact rails 152R are to be formed) using photolithography and etching processes until the source/drain features 128 are exposed. In some embodiments, the contact trenches for the contact rails 152R expose the isolation structure 100, and may further extend into the isolation structure 100. In some embodiments, the gate-cut features 150B are partially recessed. The etch process may include dry etching such as reactive ion etch (RIE), neutral beam etch (NBE), inductive coupled plasma (ICP) etch, capacitively coupled plasma (CCP) etch, another suitable method, or a combination thereof.

Contact liners 154 are formed along the sidewalls of the contact trenches using a deposition process and an etching back process, in accordance with some embodiments. In some embodiments, the contact liners 154 are made of an insulating material such as a dielectric material (e.g., SiC, LaO, AlO, AlON, ZrO, HfO, SiN, ZnO, ZrN, ZrAlO, TiO, TaO, YO, TaCN, ZrSi, SiOCN, SiOC, SiCN, SiN, HfSi, or SiO); or undoped silicon (Si). Silicide layers (not shown) may be formed on the exposed surfaces of the source/drain features 128, in accordance with some embodiments. In some embodiments, the silicide layers are made of WSi, NiSi, TiSi and/or CoSi.

Afterward, one or more conductive materials for the contact plugs 152 and contact rails 152R are deposited to overfill the contact trenches, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the second interlayer dielectric layer 146 are planarized using, for example, CMP.

The contact plugs 152 and the contact rails 152R may have a multilayer structure. For example, a barrier/adhesive layer (not shown) may optionally be deposited along the sidewalls and the bottom surfaces of the contact trenches. The barrier/adhesive layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact trenches. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

An etching stop layer 156 and a second interlayer dielectric layer 158 are sequentially formed over the semiconductor structure 100_1, as shown in FIGS. 2F-1 to 2F-3, in accordance with some embodiments. In some embodiments, the etching stop layer 156 is made of dielectric material, such as silicon nitride (SiN), silicon oxide (SiO₂), silicon oxynitride (SiON), silicon carbide (SiC), oxygen-doped silicon carbide (SiC:O), oxygen-doped silicon carbonitride (Si(O)CN), or a combination thereof. In some embodiments, the second interlayer dielectric layer 158 is made of dielectric material, such as USG, BPSG, FSG, PSG, BSG, and/or another suitable dielectric material. In some embodiments, the etching stop layer 156 and the second interlayer dielectric layer 158 are deposited using CVD (such as HDP-CVD, PECVD, HARP or FCVD), another suitable technique, or a combination thereof.

A via 160 and a vail rail 160R are formed in and/or through the etching stop layer 156 and the second interlayer dielectric layer 158, as shown in FIGS. 2F to 2F-3, in accordance with some embodiments. The via 160 lands on the contact plug 152, and the vail rail 160R lands on the contact rails 152R and the gate rails 144R, in accordance with some embodiments. In some embodiments, the via rail 160R extends in the X direction.

The via 160 are shown as dash lines in FIG. 2F-1, which indicates that it is not in the cross-sectional view. Although not shown, the vias 160 may also be formed to land on the final gate stacks 144_5 in the functional circuit cell region FC. The vias 160, electrically connected to source/drain terminals of the nanostructure transistors through the contact plugs 152, may be also referred to as source/drain vias (VS or VD), in accordance with some embodiments. The vias 160, electrically connected to the gate terminals of the nanostructure transistors, may be also referred to as gate vias (VG).

In some embodiments, the formation of the via 160 and via rail 160R includes patterning the second interlayer dielectric layer 158 and the etching stop layer 156 to form via openings (where the via 160 and via rail 160R are to be formed) using photolithography and etching processes. The etching process may include dry etching such as RIE, NBE, ICP etch, CCP etch, another suitable method, or a combination thereof. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the second interlayer dielectric layer 158 are planarized using, for example, CMP.

The via 160 and via rail 160R may have a multilayer structure. For example, a barrier/adhesive layer (not shown) may optionally be deposited along the sidewalls and the bottom surfaces of the via openings. The barrier layer may be made of Ta, TaN, Ti, TiN, CoW, another suitable material, or a combination thereof. A metal bulk layer is then deposited on the barrier/adhesive layer (if formed) to fill the remainder of the via openings. In some embodiments, the metal bulk layer is made of one or more conductive materials, such as Co, Ni, W, Ti, Ta, Cu, Rh, Ir, Pt, Al, Ru, Mo, or a combination thereof.

The semiconductor structure 100_1 may undergo further frontside BEOL processes to form various interconnection conductive features (not shown) over the semiconductor structure 100_1, such as frontside metal layers (e.g., M1-M10) and vias between neighboring two metal layers.

FIGS. 2G-1, 2G-2 and 2G-3 are cross-sectional views of a semiconductor structure 100_1 after the removal of the substrate 102 corresponding to line X-X, line Y1-Y1 and line Y2-Y2 of FIG. 2F.

The semiconductor structure 100_1 (or the semiconductor substrate 102) is flipped upside down, in accordance with some embodiments. In some embodiments, a carrier substrate (not shown) may be formed over and seal the frontside of the semiconductor structure 100_1 before flipping the semiconductor structure 100_1 to protect the frontside components of the semiconductor structure 100_1 during subsequent backside processes. After flipping the semiconductor structure 100_1, the backside surface of the substrate 102 (or the backside of the semiconductor structure 100_1) faces upward, in accordance with some embodiments. The substrate 102 are planarized from the backside of the semiconductor structure 100_1 using such as CMP, grinding process, an etching process, or a combination thereof until the isolation structure 110 are exposed, as shown in FIGS. 2G-1 to 2G-3, in accordance with some embodiments.

FIGS. 2H-1, 2H-2 and 2H-3 are cross-sectional views of a semiconductor structure 100_1 after the formation of a trench 162 corresponding to line X-X, line Y1-Y1 and line Y2-Y2 of FIG. 2F.

A patterning process is performed on the semiconductor structure 100_1 to form a trench 162 through the isolation structure 110 in the electrical connection cell region EC, as shown in FIGS. 2H-1 to 2H-3, in accordance with some embodiments. The patterning process may include photolithography and etching process. The etching process may include dry etching such as RIE, NBE, ICP etch, CCP etch, another suitable method, or a combination thereof. The trench 162 exposes the backside surfaces (i.e., the top surfaces in the current schematics) of the contact rails 152R, the gate rails 144R, the gate spacer layers 118, and the contact etching stop layer 130, in accordance with some embodiments.

In some embodiments, the gate dielectric layer 146 of the gate rails 144R are removed, and the metal gate electrode layer 148 of the gate rails 144R are exposed. In some embodiments, the sidewalls of the contact rails 152R and the gate rails 144R are exposed from the trench 162.

In some embodiments, an opening 163 may be optionally formed in the patterning process for forming the trench 162 or using another patterning process. The patterning process removes the lower fin element 104L, the semiconductor isolation feature 124 and the dielectric isolation feature 126, and the opening 163 exposes the backside surfaces (i.e., the top surfaces in the current schematics) of the source/drain features 128, in accordance with some embodiments.

FIG. 21 is a plan view of a semiconductor structure 100_1 after the formation of a through via 166. FIGS. 2I-1, 2I-2 and 2I-3 are cross-sectional views corresponding to line X-X, line Y1-Y1 and line Y2-Y2 of FIG. 21. These cross-sectional views illustrate the semiconductor structure 100_1 after flipping upside down, and thus the frontside of the semiconductor structure 100_1 faces upward, in accordance with some embodiments.

A through via 166 is formed in the trench 162, and a backside via 167 is formed in the opening 163, in FIGS. 2I to 2I-3, in accordance with some embodiments. The through via 166 lands on and are electrically connected to the gate rails 144R and the contact rails 152R, in accordance with some embodiments. The backside via 167 lands on and are electrically connected to the source/drain features 128, in accordance with some embodiments. The through via 166 may be referred to a feed through via (FTV).

In some embodiments, the formation of the through via 166 and the backside via 167 includes depositing one or more conductive materials to overfill the trench 162 and the opening 163, in accordance with some embodiments. A silicide layer (not shown) may be formed on the exposed backside surface of the source/drain feature 128, in accordance with some embodiments. In some embodiments, the silicide layers are made of WSi, NiSi, TiSi and/or CoSi. In some embodiments, one or more conductive materials are deposited using CVD, PVD, e-beam evaporation, ALD, ECP, ELD, another suitable method, or a combination thereof to overfill the contact openings. The one or more conductive materials over the upper surface of the dielectric layer 167 are planarized using, for example, CMP.

The through via 166 and the via 167 may have a multilayer structure. For example, a barrier/adhesive layer (not shown) may optionally be deposited along the sidewalls and the bottom surfaces of the trench 162. The barrier/adhesive layer may be made of Ta, TaN, Ti, TiN, CoW, another suitable material, or a combination thereof. A metal bulk layer is then deposited on the barrier/adhesive layer (if formed) to fill the remainder of the trench 162. In some embodiments, the metal bulk layer is made of one or more conductive materials, such as Co, Ni, W, Ti, Ta, Cu, Rh, Ir, Pt, Al, Ru, Mo, or a combination thereof.

In some embodiments, the through via 166 extends in the X direction. That is, the through via 166 has a longitudinal axis parallel to the X direction, in accordance with some embodiments. In some embodiments, the X-direction extending boundaries of the through via 166 correspond to and overlaps the gate-cut features 150B. That is, the width of the through via 166 (in the Y direction) is greater than the spacing between the gate-cut features 150B, in accordance with some embodiments.

The via rail 160R, the gate rails 144R and the contact rails 152R and the through via 166 combine to form an electrical connection structure in the electrical connection cell region EC, in accordance with some embodiments. The electrical connection structure is configured to transfer an electronic signal from a driver cell to a receiver cell, and/or to supply power (e.g., VDD, VSS, etc.), in accordance with some embodiments. The electrical connection structure is electrically coupled to the gate terminal and/or the source/drain terminals of the functional circuit in the functional circuit cell region FC through the frontside interconnection conductive features and/or the backside interconnection conductive features, in accordance with some embodiments.

In some embodiments, the gate rails 144R may be formed extending into a deeper position than the bottom surfaces of the contact rails 152R, e.g., by about 2 nm to about 50 nm. In some embodiments, the bottom surfaces of the gate rails 144R are lower than the bottom surfaces of the final gate stack 144 (e.g., 144_5) in the functional circuit cell region FC, and the bottom surfaces of the contact rails 152R are lower than the bottom surfaces of the contact plugs 152 in the functional circuit cell region FC. In some other embodiments, the bottom surfaces of the gate rails 144R are higher than the bottom surfaces of the final gate stack 144 (e.g., 144_5) in the functional circuit cell region FC, and the bottom surfaces of the contact rails 152R are higher than the bottom surfaces of the contact plugs 152 in the functional circuit cell region FC.

In accordance with the embodiments of the present disclosure, the electrical connection structure includes both the plurality of gate rails 144R and the plurality of contact rails 152R, and thus the resistance of the electrical connection structure may be significantly reduced. Therefore, the IR voltage drop of the resulting semiconductor device may be reduced. In addition, as compared with the case without the gate rails 144R, the electrical connection structure of the embodiments may utilize a lower substrate area to obtain a low resistance value and reduce the signal cross-talk between frontside metal layers and backside metal layers.

Furthermore, because the gate rails 144R and the contact rails 152R have patterns that are similar to those of the final gate stacks 144 and contact plugs 152 in the functional circuit cell regions FC, the stability of the process for forming the final gate stacks 144 and the stability of the patterning process used for forming the contact plugs 152 (and 152R) may not be negatively impacted. Therefore, the process of manufacturing the electrical connection structure may be easily integrated into the CMOS manufacturing process.

The through via 166 is in direct contact with the backside surfaces (i.e., the top surfaces in the current schematics) and the sidewalls of the metal gate electrode layer 148 of the gate rails 144R and the contact rails 152R, in accordance with some embodiments. As a result, the contact area between through via 166 and the gate rails 144R and/or the contact area between through via 166 the contact rails 152R may increase, which may further reduce the resistance of the electrical connection structure.

The semiconductor structure 100_1 may undergo further backside BEOL processes to form various interconnection conductive features (not shown) over the backside of the semiconductor structure 100_1, such as backside second metal layers (e.g., B_M1 to B_M8), vias between neighboring two metal layers. Although the embodiments are discussed in the context of the nano-sheet transistors, the embodiments of the present disclosure may be applied to planar transistors, FinFET transistors, nano-wire transistors, fork-sheet transistors, CFET, and the like.

FIGS. 3A and 3B are schematic views illustrating the electrical transmission route including an electrical connection cell region EC, in accordance with some embodiments of the disclosure.

In some embodiments, a signal from a driver in a functional circuit cell region FC1 is transferred to a receiver in a functional circuit cell region FC2, as shown in FIG. 3A. The electrical transmission route sequentially includes a line in a frontside metal layer M1, an electrical connection structure in an electrical connection cell region EC1, a line in a backside metal layer BM1, an electrical connection structure in an electrical connection cell region EC2 and another line in the frontside metal layer M1, in accordance with some embodiments. The electrical connection structure can introduce the signal from the frontside to the backside of the device, and thus the routing density of the frontside metal lines may be improved.

In some embodiments, the backside metal layer BM1 includes power supply lines (e.g., power rails Vss or Vdd), as shown in FIG. 3B. An electrical connection structure in an electrical connection cell region EC3 introduces the power from the backside metal layer BM1 to the frontside metal layer M1, to power functional circuits in functional circuit cell region FC3 and FC4. In some embodiments, the circuit in the functional circuit cell region FC4 may be powered from dual sides.

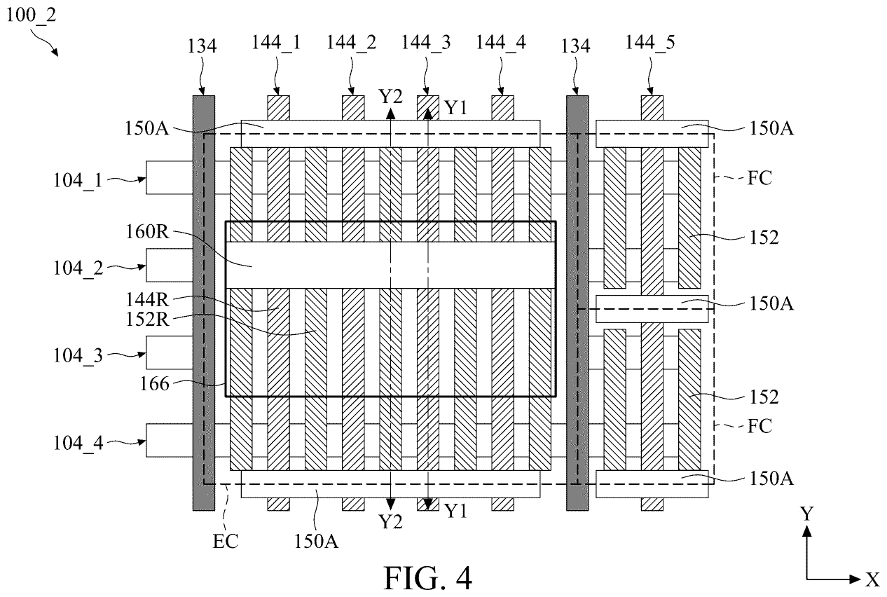

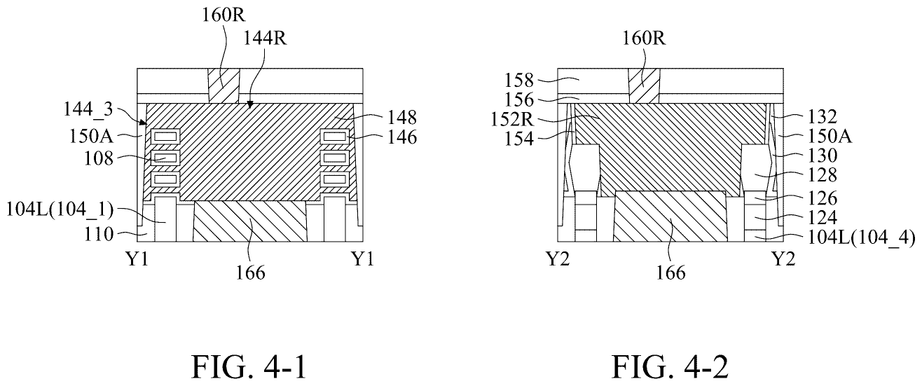

FIG. 4 is a layout (top view) illustrating a semiconductor structure 100_2, in accordance with some embodiments of the disclosure. FIGS. 4-1 and 4-2 are cross-sectional views of the semiconductor structure corresponding to line Y1-Y1 and line Y2-Y2 of FIG. 4. The embodiments of FIGS. 4 to 4-2 are similar to the embodiments of FIGS. 2A to 2I-3, except that the gate-cut features 150B are omitted. The segments of the final gate stacks 144_1 to 144_4 sandwiched between the gate-cut features 150A in the electrical connection cell region EC are referred to gate rails 144R, in accordance with some embodiments. In some embodiments, the gate rails 144R are longer than or equal to in the Y direction the contact rails 152R.

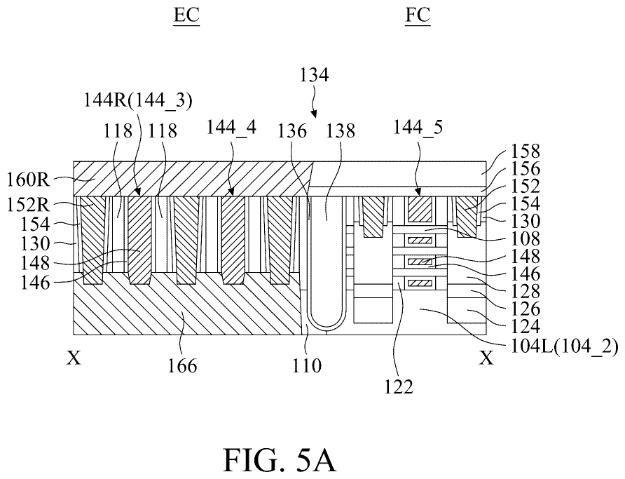

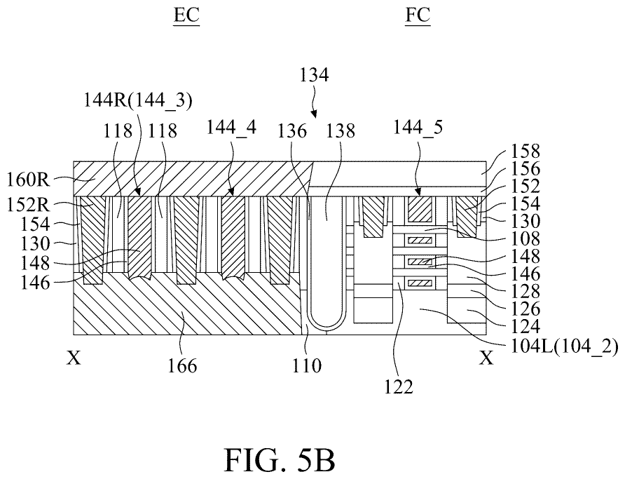

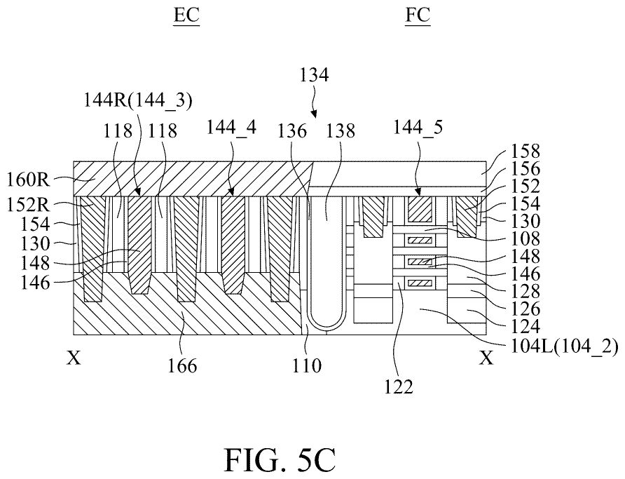

FIGS. 5A, 5B and 5C are modifications of the semiconductor structure 100_1 of FIG. 2I-1, in accordance with some embodiments of the disclosure. In some embodiments, the bottom surfaces of the gate rails 144R are located at substantially the same position as the bottom surface of the contact rails 152R, as shown in FIG. 5A. In some embodiments, the bottom surfaces of the gate rails 144R are located at a higher position than the bottom surfaces of the contact rails 152R, because in the etching process for forming the trench 162 the etching rate (or etching amount) of the gate rails 144R is faster (or greater) than the etching rate (or etching amount) of the contact rails 152R, as shown in FIG. 5B. In some embodiments, the contact rails 152R may be formed extending into a deeper position than the bottom surfaces of the gate rails 144R, e.g., by about 2 nm to about 50 nm, as shown in FIG. 5C.

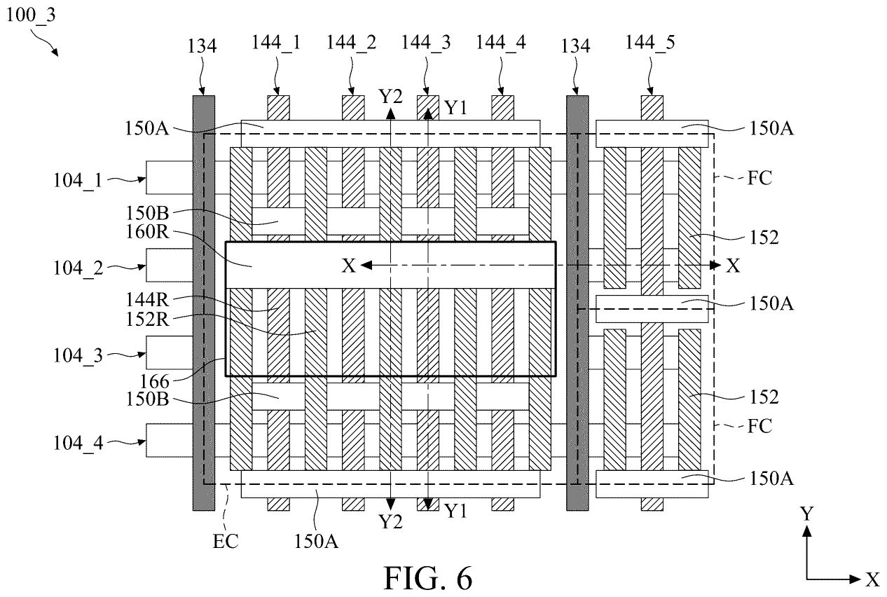

FIG. 6 is a layout (top view) illustrating a semiconductor structure 100_3, in accordance with some embodiments of the disclosure. The embodiments of FIG. 6 are similar to the embodiments of FIGS. 2A to 2I-3, except that the through via 166 does not overlap the gate-cut features 150B. The width of the through via 166 (in the Y direction) is less than or equal to the spacing between the gate-cut features 150B, in accordance with some embodiments.

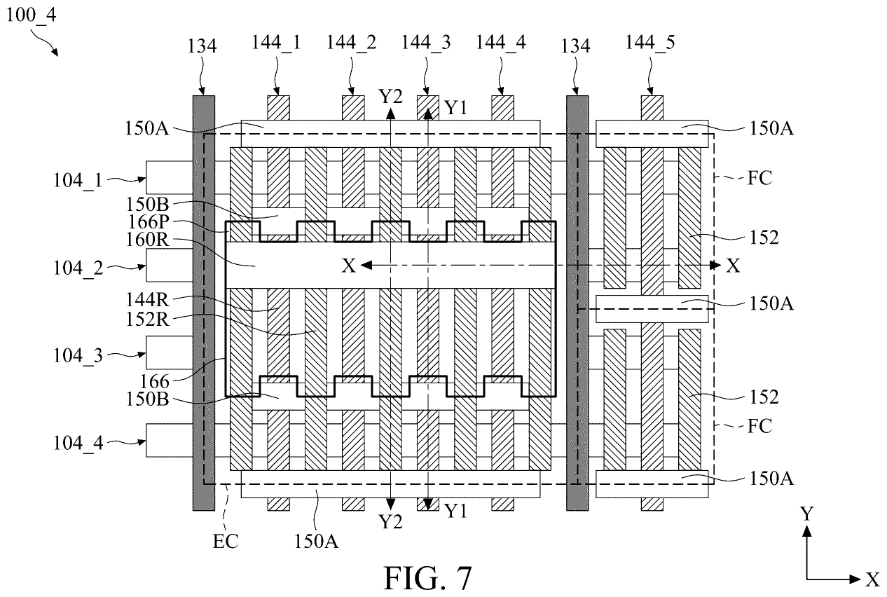

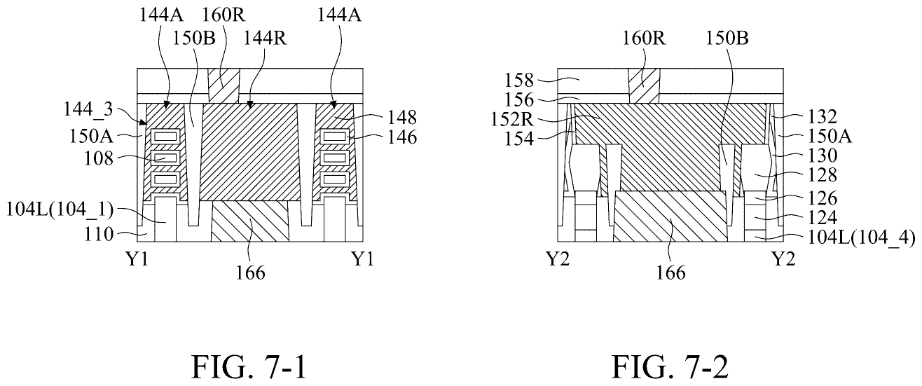

FIG. 7 is a layout (top view) illustrating a semiconductor structure 100_4, in accordance with some embodiments of the disclosure. FIGS. 7-1 and 7-2 are cross-sectional views of the semiconductor structure corresponding to line Y1-Y1 and line Y2-Y2 of FIG. 7. The embodiments of FIGS. 7 to 7-2 are similar to the embodiments of FIG. 6, except that the through via 166 includes a jog structure. As the term is used herein, “jog” refers to a dent or protrusion on one or both sides of a feature.

In some embodiments, the through via 166 includes protrusions 166P on the opposite sides of the through via 166 extending in the X direction. The protrusions 166P of the through via 166 correspond to the contact rails 152R, and extend about 2-50 nm in the Y direction to overlap the gate-cut features 150B, in accordance with some embodiments. In some other embodiments, the protrusions 166P may correspond to the gate rails 144R.

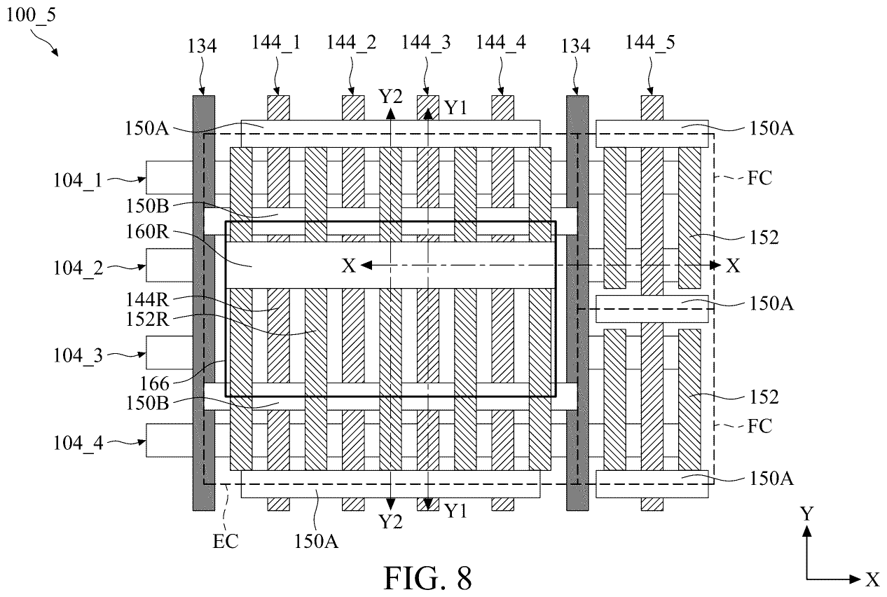

FIG. 8 is a layout (top view) illustrating a semiconductor structure 100_5, in accordance with some embodiments of the disclosure. The embodiments of FIG. 8 are similar to the embodiments of FIGS. 2A to 2I-3, except that the gate-cut features 150B extend to overlap the insulating strips 134.

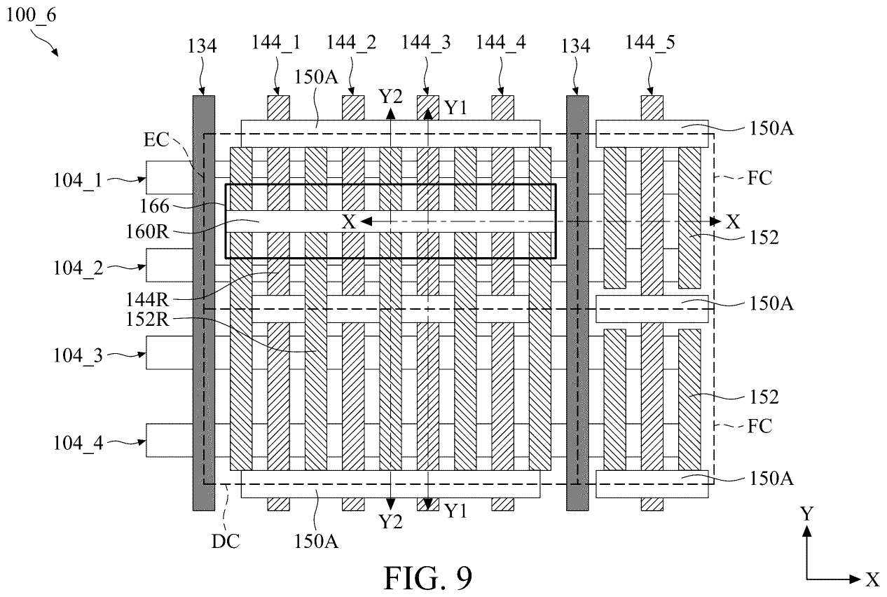

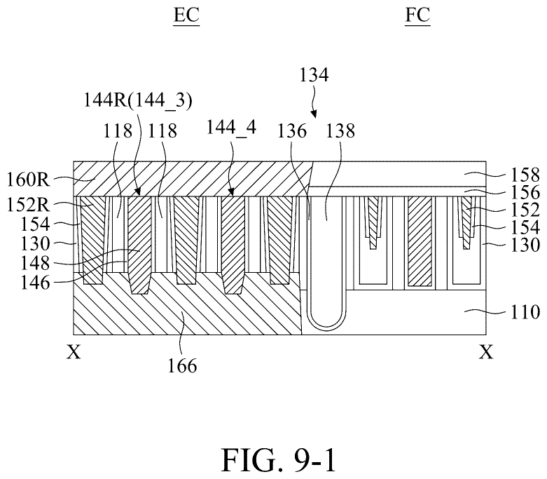

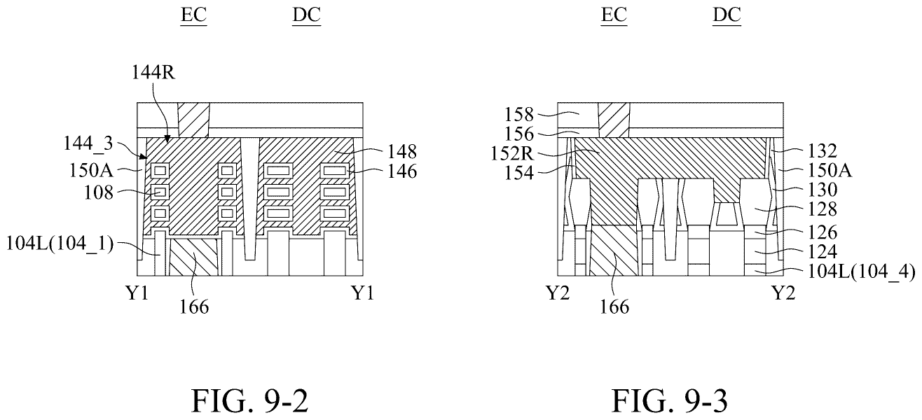

FIG. 9 is a layout (top view) illustrating a semiconductor structure 100_6, in accordance with some embodiments of the disclosure. FIGS. 9-1, 9-2 and 9-3 are cross-sectional views of the semiconductor structure corresponding to line X-X, line Y1-Y1 and line Y2-Y2 of FIG. 9. The embodiments of FIGS. 9 to 9-3 are similar to the embodiments of FIGS. 2A to 2I-3, except that the cell height (dimension in the Y direction) of the electrical connection cell region EC is equal to the cell height (dimension in the Y direction) of the functional circuit cell regions FC.

The electrical connection cell region EC and a functional circuit cell region FC are arranged in the first row, and a dummy cell DC and another a functional circuit cell region FC are arranged in the second row immediately below the first row, as shown in FIG. 9, in accordance with some embodiments. In some embodiments, the active regions 104_1 and 104_2 are continuous oxide definition (CNOD) and extend through the electrical connection cell region EC and the functional circuit cell region FC.

In some embodiments, the active regions 104_1 and 104_2 include a jog structure, which may be formed by the second active region patterning process. In specific, the portions of the active regions 104_1 and 104_2 in the electrical connection cell region EC are partially removed to enlarge the space between the active regions 104_1 and 104_2 in the electrical connection cell region EC, in accordance with some embodiments.

As a result, the portions of the active regions 104_1 and 104_2 in the electrical connection cell region EC are narrower than the portions of the active regions 104_1 and 104_2 outside the electrical connection cell region EC (e.g., in the functional circuit cell region FC), in accordance with some embodiments. In some embodiments, the spacing between the active regions 104_1 and 104_2 in the electrical connection cell region EC is wider than the spacing between the active regions 104_1 and 104_2 outside the electrical connection cell region EC.

In some embodiments, the gate-cut features 150B are omitted, and the segments of the final gate stacks 144_1 to 144_4 sandwiched between the gate-cut features 150A in the electrical connection cell region EC are referred to gate rails 144R. In some embodiments, the through via 166 is formed in the space between the narrower portions of the active regions 104_1 and 104_2. In accordance with some embodiments, the electrical connection structure includes both the gate rails 144R and the contact rails 152R, the resistance of the electrical connection structure may be significantly reduced.

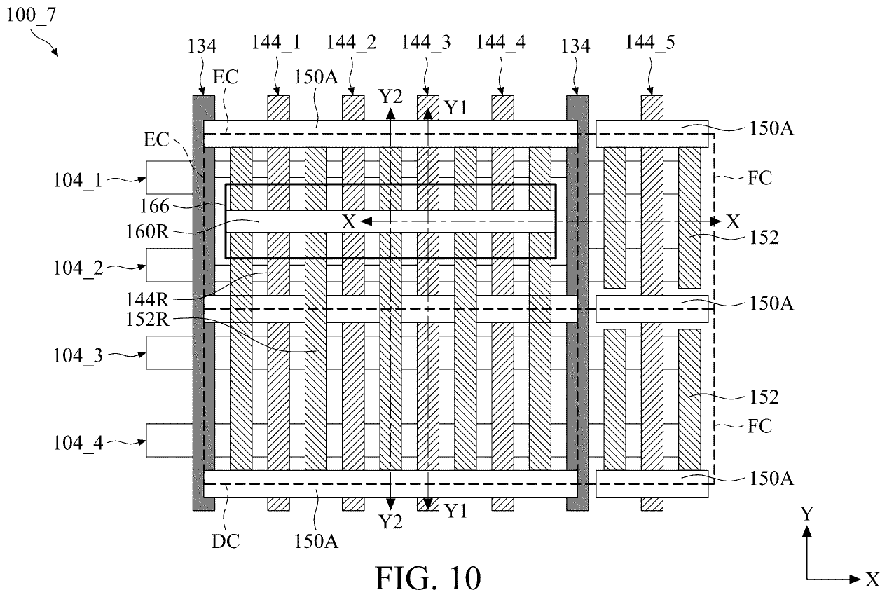

FIG. 10 is a layout (top view) illustrating a semiconductor structure 100_7, in accordance with some embodiments of the disclosure. The embodiments of FIG. 10 are similar to the embodiments of FIGS. 9 to 9-3, except that the gate-cut features 150A corresponding to the boundaries of the electrical connection cell region EC extend to overlap the insulating strips 134.

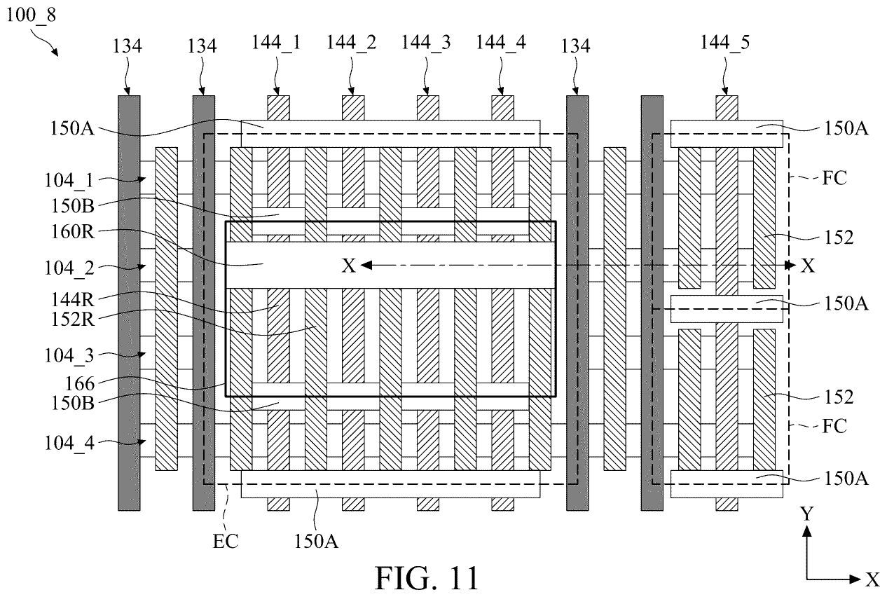

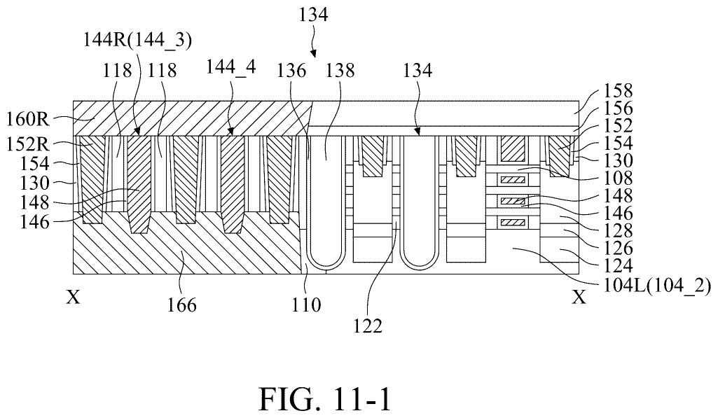

FIG. 11 is a layout (top view) illustrating a semiconductor structure 100_8, in accordance with some embodiments of the disclosure. FIG. 11-1 is a cross-sectional view of the semiconductor structure corresponding to line X-X of FIG. 11. The embodiments of FIGS. 11 and 11-1 are similar to the embodiments of FIGS. 2A to 2I-3, except that the two insulating strips 134 are formed between the electrical connection cell region EC and the functional circuit cell regions FC. Therefore, the electrical connection cell region EC is separate from the functional circuit cell regions FC by two gate pitches, which may improve the performance of the resulting semiconductor device, e.g., variation of the threshold voltage.

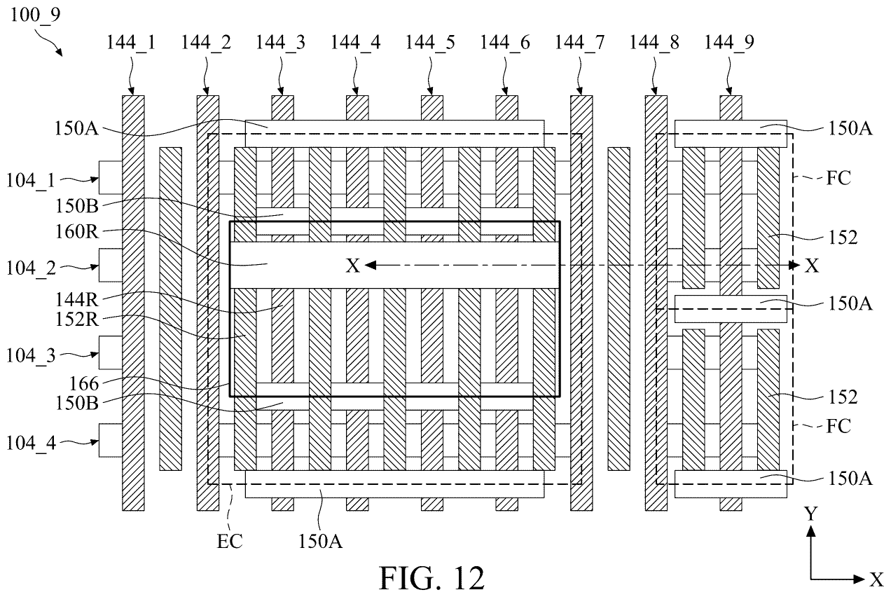

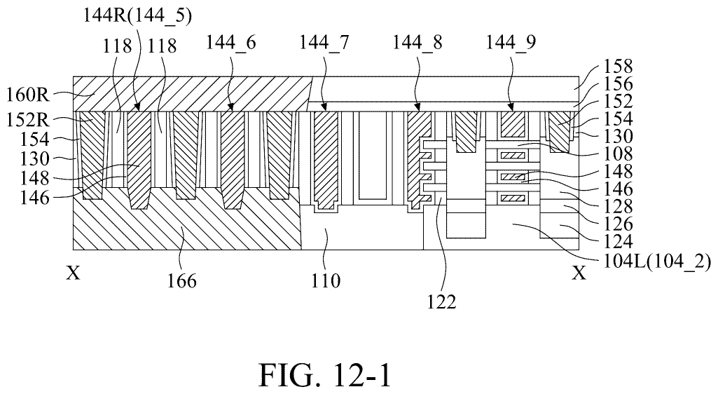

FIG. 12 is a layout (top view) illustrating a semiconductor structure 100_9, in accordance with some embodiments of the disclosure. FIG. 12-1 is a cross-sectional view of the semiconductor structure corresponding to line X-X of FIG. 12. The embodiments of FIGS. 12 and 12-1 are similar to the embodiments of FIGS. 2A to 2I-3, except that the insulating strips 134 are omitted. In the second active region patterning process, the portions of active regions 104_1 to 104_4 between the electrical connection cell region EC and the functional circuit cell regions FC are also removed, and thus the electrical isolation therebetween may improve. The active regions 104_1 to 104_4 may be also referred to as cut OD (COD) features.

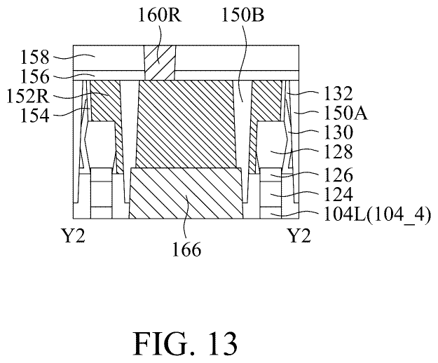

FIG. 13 is a modification of the semiconductor structure FIG. 2I-3, in accordance with some embodiments of the disclosure. The embodiments of FIG. 13 are similar to the embodiments of FIGS. 2A to 2I-3, except that in the patterning process for forming the contact trenches, the gate-cut features 150B are substantially not recessed. As a result, each of the contact plugs 152R includes several partitions separated from the gate-cut features 150B, in accordance with some embodiments.

All of the dummy gate structures 112 are replaced with the final gate stacks 144 (including 144_1 to 144_9), in accordance with some embodiments. The electrical connection cell region EC is separate from the functional circuit cell regions FC by two gate pitches (e.g., by the final gate stacks 144_7 and 144_8), in accordance with some embodiments. In some embodiments, the final gate stacks 144_1, 144_2, 144_7 and 144_8 are isolation gate, which are not electrically connected to interconnection conductive features.

As described above, the aspect of the present disclosure is directed to a semiconductor structure with an electrical connection structure and a method for forming the same. The electrical connection structure includes both the gate rails 144R and the contact rails 152R, the resistance of the electrical connection structure may be significantly reduced. Therefore, the IR voltage drop of the resulting semiconductor device may be reduced.

Embodiments of a semiconductor structure are provided. The semiconductor structure may include an electrical connection structure and a function circuit electrically connected to the electrical connection structure. The electrical connection structure includes a plurality of gate rails, which are formed together with the gate stacks of the function circuit. The electrical connection structure further includes a plurality of contact rails, which are formed together with the contact plugs of the function circuit. Therefore, the process of manufacturing the electrical connection structure may be easily integrated into the CMOS manufacturing process, and the electrical connection structure may have a low resistance.

In some embodiments, a method for forming a semiconductor structure is provided. The method includes forming a plurality of gate rails over a first cell region of a substrate, and forming a plurality of contact rails over the first cell region of a substrate. The gate rails and the contact rails are arranged in an alternating manner. The method further includes removing the gate dielectric layers of the plurality of gate rails to expose the gate electrode layers of the gate rails, and forming a through via under the plurality of gate rails and the plurality of contact rails.

In some embodiments, a method for forming a semiconductor structure is provided. The method includes forming a first active region and a second active region over a substrate, forming an isolation structure surrounding lower portions of the first active region and the second active region, forming a gate electrode layer across the first active region, the second active region and the isolation structure, and etching the isolation structure to form a trench between the first active region and the second active region. The trench exposes a backside surface of the gate electrode layer. The method further includes forming a through via in the trench.

In some embodiments, a semiconductor structure is provided. The semiconductor structure includes a first lower fin element, an isolation structure surrounding the first lower fin element, and a functional circuit and an electrical connection structure. The functional circuit includes a first set of nanostructures over the lower fin element, and a gate stack wrapping around the first set of nanostructures. The electrical connection structure includes a through via embedded in the isolation structure, and a plurality of gate rails and a plurality of contact rails that are arranged horizontally in an alternating manner on the through via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a plurality of gate rails over a first cell region of a substrate;
forming a plurality of contact rails over the first cell region of the substrate, wherein the gate rails and the contact rails are alternatingly arranged;
removing gate dielectric layers of the plurality of gate rails to expose gate electrode layers of the gate rails; and
forming a through via under the plurality of gate rails and the plurality of contact rails.

2. The method for forming the semiconductor structure as claimed in claim 1, wherein the through via is in direct contact with the gate electrode layers of the gate rails and the plurality of contact rails.

3. The method for forming the semiconductor structure as claimed in claim 1, further comprising:
forming an active region over the first cell region of the substrate;
forming a plurality of gate stacks across the active region over the first cell region of the substrate; and
cutting through the plurality of gate stacks into the plurality of gate rails using a gate-cut feature.

4. The method for forming the semiconductor structure as claimed in claim 3, wherein in a top view, the gate-cut feature partially overlaps the through via.

5. The method for forming the semiconductor structure as claimed in claim 1, wherein the through via includes a plurality of protrusions, and the protrusions of the through via extend from a sidewall of the through via and overlaps the respective contact rails.

6. The method for forming the semiconductor structure as claimed in claim 1, further comprising:
forming an isolation structure over the substrate, wherein the plurality of gate rails and the plurality of contact rails are formed on the isolation structure;
flipping the substrate;
removing the substrate;
etching the isolation structure to form a trench; and
forming the through via in the trench.

7. The method for forming the semiconductor structure as claimed in claim 6, wherein during the etching of the isolation structure, the plurality of gate rails are etched at a first etching rate, and the plurality of contact rails are etched at a second etching rate that is slower than the first etching rate.

8. The method for forming the semiconductor structure as claimed in claim 1, further comprising:
forming a set of nanostructures over a second cell region of the substrate; and
forming a gate stack to surround the nanostructures, wherein the through via is electrically connected to the gate stack.

9. The method for forming the semiconductor structure as claimed in claim 1, further comprising:
forming a set of nanostructures over a second cell region of the substrate;
forming a source/drain feature adjoining the set of nanostructures;
forming a backside via under the source/drain feature; and
forming a power rail under and electrically connected to the backside via and the through via.

10. The method for forming the semiconductor structure as claimed in claim 9, wherein a cell height of the first cell region is twice a cell height of the second cell region.

11. A method for forming a semiconductor structure, comprising:
forming a first active region and a second active region over a substrate;
forming an isolation structure surrounding lower portions of the first active region and the second active region;
forming a gate electrode layer across the first active region, the second active region and the isolation structure;
etching the isolation structure to form a trench between the first active region and the second active region, wherein the trench exposes a backside surface of the gate electrode layer; and
forming a through via in the trench.

12. The method for forming the semiconductor structure as claimed in claim 11, further comprising:
forming a first source/drain feature and a second source/drain feature on the first active region and the second active region, respectively; and
forming a contact rail on the first source/drain feature and the second source/drain feature, wherein the trench further exposes a backside surface of the contact rail.

13. The method for forming the semiconductor structure as claimed in claim 11, further comprising:
forming a first dummy gate structure, a second dummy gate structure and a third dummy gate structure across the first active region, the second active region and the isolation structure;
replacing the first dummy gate structure and the third dummy gate structure with a first insulating strip and a second insulating strip, respectively; and
replacing the second dummy gate structure with the gate electrode layer, wherein the gate electrode layer is located between the first insulating strip and the second insulating strip.

14. The method for forming the semiconductor structure as claimed in claim 11, wherein the trench exposes sidewalls of the gate electrode layer.

15. The method for forming the semiconductor structure as claimed in claim 11, further comprising:
forming a stack of alternating first semiconductor layers and second semiconductor layers over the substrate;
patterning the stack to form the first active region and the second active region;
removing the first semiconductor layers of the first active region and the second active region, wherein the gate electrode layer surrounds the second semiconductor layers of the first active region and the second active region; and
forming a first gate-cut feature and a second gate-cut feature through the gate electrode layer, wherein the trench exposes the first gate-cut feature and the second gate-cut feature.

16. A semiconductor structure, comprising:
a first lower fin element;
an isolation structure surrounding the first lower fin element;
a functional circuit, comprising:
a first set of nanostructures over the first lower fin element; and
a gate stack wrapping around the first set of nanostructures; and
an electrical connection structure, comprising:
a through via embedded in the isolation structure; and
a plurality of gate rails and a plurality of contact rails arranged horizontally in an alternating manner on the through via.

17. The semiconductor structure as claimed in claim 16, further comprising:
at least one insulating strip separating the electrical connection structure from the functional circuit, wherein the at least one insulating strip extends in a horizontal direction that is parallel to longitudinal axes of the plurality of gate rails.

18. The semiconductor structure as claimed in claim 16, wherein the electrical connection structure is electrically coupled to the functional circuit.

19. The semiconductor structure as claimed in claim 16, further comprising:
a second lower fin element and a third lower fin element interposed by the through via of the electrical connection structure, wherein a width of the second lower fin element is thinner than a width of the first lower fin element.

20. The semiconductor structure as claimed in claim 16, wherein the electrical connection structure further comprises a via rail on and in direct contact with the plurality of gate rails and the plurality of contact rails.
